(19) United States
(12) Patent Application Publication
(10) Pub. No.: US 2025/0324667 A1
(43) Pub. Date: Oct. 16, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Jhon-Jhy LIAW, Zhudong Township (TW)

(21) Appl. No.: 18/631,262

(22) Filed: Apr. 10, 2024

(51) Int. Cl. H01L 29/423; H01L 21/762; H01L 29/06; H01L 29/66; H01L 29/775; H01L 29/786

(52) U.S. Cl. CPC H10D 30/6735; H01L 21/76224; H10D 30/014; H10D 30/43; H10D 30/6757; H10D 62/121; H10D 64/017; H10D 64/018

(57) ABSTRACT

A semiconductor structure is provided. The semiconductor structure includes a first transistor and a second transistor. The first transistor includes a first plurality of nanostructures over a first lower fin element, and a first source/drain feature adjoining the first plurality of nanostructures. The second transistor includes a second plurality of nanostructures over a second lower fin element, and a second source/drain feature adjoining the second plurality of nanostructures. The semiconductor structure further includes a first dielectric isolation feature between the first source/drain feature and the first lower fin element, and a second dielectric isolation feature between the second source/drain feature and the second lower fin element. The first and second lower fin elements have a first conductivity type, the first source/drain feature has the first conductivity type, and the second source/drain feature has a second conductivity type.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a cell region of a semiconductor structure, in accordance with some embodiments.

FIGS. 3A, 3B-1, 3C-1, 3D-1, 3E-1, 3F-1, 3G-1, 3H-1 and 3I-1 are cross-sectional views illustrating the formation of a semiconductor structure at various intermediate stages, in accordance with some embodiments of the disclosure.

FIGS. 3B-2, 3C-2, 3D-2, 3E-2, 3F-2, 3G-2, 3H-2 and 3I-2 are cross-sectional views illustrating the formation of a semiconductor structure at various intermediate stages, in accordance with some embodiments of the disclosure.

FIGS. 3B-3, 3C-3, 3D-3, 3E-3, 3F-3, 3G-3, 3H-3 and 3I-3 are cross-sectional views illustrating the formation of a semiconductor structure at various intermediate stages, in accordance with some embodiments of the disclosure.

FIG. 3I-4 is a plan view illustrating the semiconductor of FIG. 3I-1 taken along plane A-A, in accordance with some embodiments of the disclosure.

FIGS. 4A-1 and 4B-1 are cross-sectional views illustrating the formation of a semiconductor structure at various intermediate stages, in accordance with some embodiments of the disclosure.

FIGS. 4A-2 and 4B-2 are cross-sectional views illustrating the formation of a semiconductor structure at various intermediate stages, in accordance with some embodiments of the disclosure.

FIGS. 4A-3 and 4B-3 are cross-sectional views illustrating the formation of a semiconductor structure at various intermediate stages, in accordance with some embodiments of the disclosure.

FIG. 4B-4 is a plan view illustrating the semiconductor of FIG. 4B-1 taken along plane B-B, in accordance with some embodiments of the disclosure.

FIGS. 5-1, 5-2 and 5-3 are a modification of the semiconductor structure of FIGS. 4B-1, 4B-2 and 4B-3, in accordance with some embodiments of the disclosure.

FIGS. 6A-1, 6B-1, 6C-1 and 6D-1 are cross-sectional views illustrating the formation of a semiconductor structure at various intermediate stages, in accordance with some embodiments of the disclosure.

FIGS. 6A-2, 6B-2, 6C-2 and 6D-2 are cross-sectional views illustrating the formation of a semiconductor structure at various intermediate stages, in accordance with some embodiments of the disclosure.

FIGS. 6A-3, 6B-3, 6C-3 and 6D-3 are cross-sectional views illustrating the formation of a semiconductor structure at various intermediate stages, in accordance with some embodiments of the disclosure.

FIGS. 7-1, 7-2 and 7-3 are cross-sectional views of a semiconductor structure, in accordance with some embodiments of the disclosure.

FIGS. 8-1, 8-2 and 8-3 are a modification of the semiconductor structure of FIGS. 7-1, 7-2 and 7-3, in accordance with some embodiments of the disclosure.

FIG. 9A is a layout of a cell region of a semiconductor structure, in accordance with some embodiments.

FIGS. 9B-1, 9B-2 and 9B-3 are cross-sectional views of a semiconductor structure, in accordance with some embodiments of the disclosure.

FIGS. 10-1, 10-2 and 10-3 are a modification of the semiconductor structure of FIGS. 3I-1, 3I-2 and 3I-3, in accordance with some embodiments of the disclosure.

FIG. 11 is a modification of the semiconductor structure of FIG. 10-2, in accordance with some embodiments of the disclosure.

FIG. 12 is a modification of the semiconductor structure of FIG. 3I-1, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The nanostructure transistors may have excellent performance in gate control capability, lower leakage current, and shrinkage capability. However, it still has a weakness in the non-gate surrounded body-to-gate interface region (e.g., the planar transistor formed by a fin bottom), and therefore may have a concern about leakage (e.g., high off-state current (e.g., Isoff)).

Embodiments of a semiconductor structure are provided. The aspect of the present disclosure is directed to a semiconductor structure including nanostructure transistors. The semiconductor structure includes the dielectric isolation features which are formed between source/drain features and a lower fin element, which may block a leakage path of the bottom planar transistor, and reduce parasitic capacitance. Therefore, the performance of the resulting semiconductor device may be enhanced. In addition, a doped region may be formed in the lower fin element, thereby forming a P-N junction in the body-to-gate interface region. Therefore, a potential leakage path caused by damage of the dielectric isolation feature due to etching processes and/or high-voltage operations may be prevented.

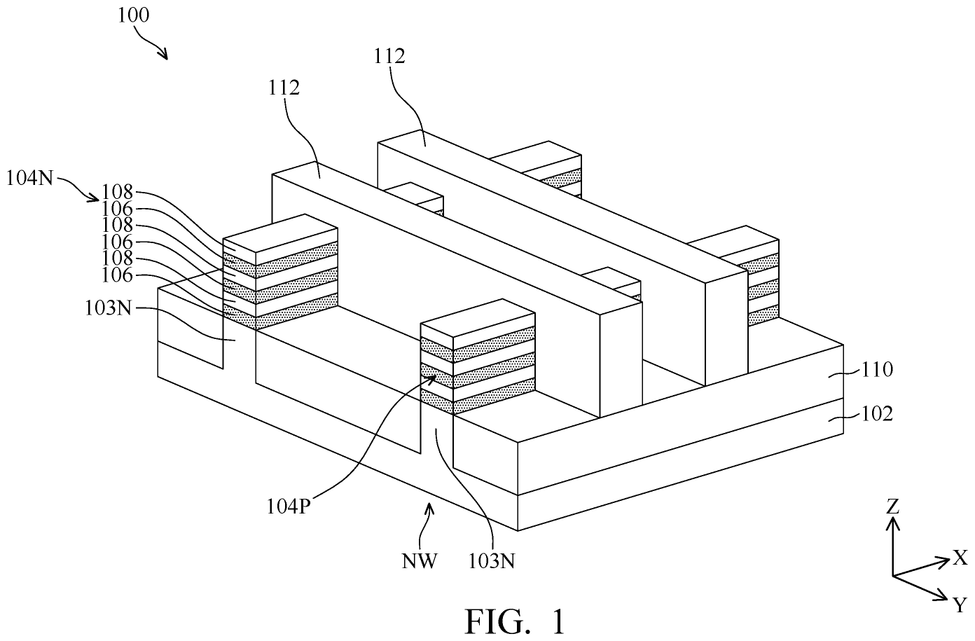

FIG. 1 is a perspective view of a semiconductor structure 100, in accordance with some embodiments of the disclosure.

The semiconductor structure 100 includes a substrate 102 and fin structures 104 (including 104N and 104P) over the substrate 102, as shown in FIG. 1, in accordance with some embodiments. An n-type well NW is formed in the substrate 102, in accordance with some embodiments. Both the fin structure 104N and the fin structure 104P are formed in the n-type well NW of the substrate 102, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

Each of the fin structures 104N and 104P includes a lower fin element 103N formed from the n-type well NW, in accordance with some embodiments. The lower fin elements 103N and 103N are surrounded by an isolation structure 110, in accordance with some embodiments. Each of the fin structures 104N and 104P further includes an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

The fin structures 104 extend in the X direction, in accordance with some embodiments. That is, the fin structures 104 have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are alternately arranged, in accordance with some embodiments. It is noted that in the present disclosure, source/drain region(s) may refer to a source or a drain, individually or collectively dependent upon the context.

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-routing direction.

Although two fin structures 104 are illustrated in FIG. 1, the semiconductor structure 100 may include more than two fin structures 104. In addition, FIG. 1 shows two gate structures 112 (or channel regions) for illustrative purposes and is not intended to be limiting. The number of fin structures and the gate structures may be dependent on the design demand of an integrated circuit and/or performance consideration of semiconductor devices.

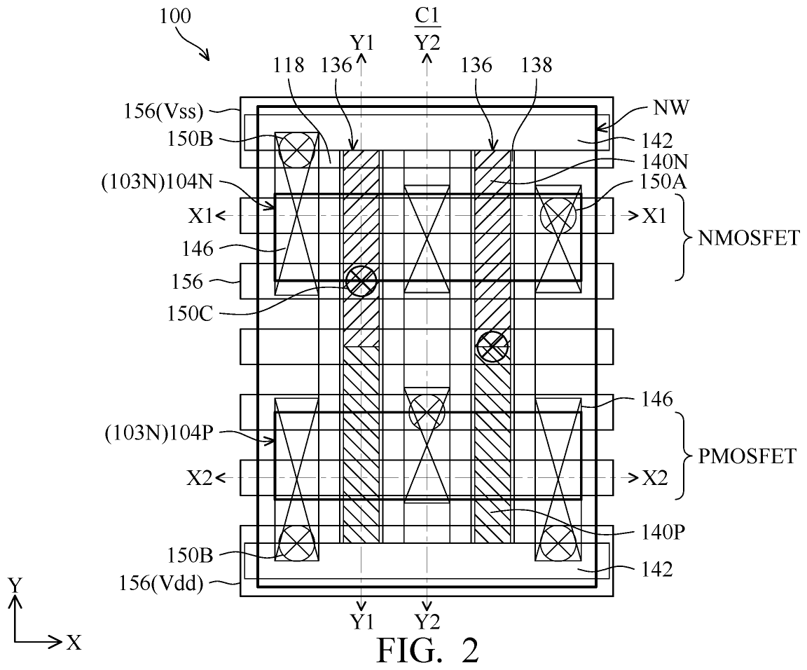

FIG. 2 is a layout (or a plan view) of a cell region C1 of a semiconductor structure 100, in accordance with some embodiments.

The semiconductor structure 100 may be or include nanostructure devices (e.g., GAA FETs), in accordance with some embodiments. The semiconductor structure 100 includes active regions 104 (including 104N and 104P) over a substrate (as shown in FIG. 1), and final gate stacks 136 across the active regions 104, in accordance with some embodiments. The active regions 104N and 104P are the fin structures 104N and 104P of FIG. 1. The substrate includes an n-type well NW, in accordance with some embodiments. Both the active regions 104N and 104P are located on the n-type well NW, in accordance with some embodiments. Each of the active regions 104 includes a lower fin element 103N and nanostructures (not shown in FIG. 2) formed over the lower element 103N, in accordance with some embodiments.

The final gate stacks 136 extend across the active regions 104N and 104P and wrap around the nanostructures of the active regions 104, in accordance with some embodiments. In some embodiments, each of the final gate stacks 136 includes a gate dielectric layer 138 and a metal gate electrode layer. The metal gate electrode layer may include an n-type work function metal material 140N and a p-type work function metal material 140P. Gate spacer layers 118 are formed along the opposite sides of the final gate stacks 136, in accordance with some embodiments.

The final gate stacks 136 are combined with the nanostructures of the active regions 104N and 104P to form nanostructure transistors, in accordance with some embodiments. The nanostructure transistors are formed at the cross points between the active regions 104 and the final gate stacks 136, in accordance with some embodiments. For example, the nanostructure transistors formed at the cross points between the n-type work function metal material 140N and the nanostructures of the active regions 104N are n-channel nanostructure transistors NMOSFET, and the nanostructure formed at the cross points between the p-type work function metal material 140P and the nanostructures of the active regions 104P are p-channel nanostructure transistors PMOSFET.

A functional circuit including four nanostructure transistors NMOSFET and PMOSFET is disposed in cell region C1, in accordance with some embodiments. Although FIG. 2 only illustrates a cell region C1, the semiconductor structure 100 may include multiple cell regions. The functional circuits in the cell regions are interconnected to form an integrated circuit, in accordance with some embodiments.

Gate-cut structures 142 extend in the X direction and cut through the gate stack 136 and the gate spacer layers 118, in accordance with some embodiments. The gate-cut structures 142 correspond to the boundaries of the cell region C1 with respect to the Y direction (extending in the X direction), in accordance with some embodiments. Contact plugs 146 are formed over the source/drain regions of the active regions 104N and 104P, in accordance with some embodiments. The contact plugs 146 are electrically connected to the source or drain terminals of the nanostructure transistors, in accordance with some embodiments.

A first-level metal layer (M1) is formed over the contact plugs 146, in accordance with some embodiments. The first-level metal layer (M1) includes several conductive lines (tracks) 156, e.g., power supply lines and signal lines, in accordance with some embodiments. The power supply lines include a Vdd power rail providing positive voltage and a Vss power rail which may be an electrical ground, in accordance with some embodiments.

The Vss power rail 156 is electrically connected to the Vss node (e.g., source terminals) of the n-channel nanostructure transistors NMOSFET through vias 150B, in accordance with some embodiments. The Vdd power rail 156 is electrically connected to the Vdd node (e.g., source terminals) of the p-channel nanostructure transistors PMOSFET through vias 150B, in accordance with some embodiments. The signal lines are configured for signal transmission and are electrically drain terminals and gate terminals of the nanostructure transistors through vias 150A and 150C, in accordance with some embodiments.

The lines 156 of the first-level metal layer M1 extend in the X direction, in accordance with some embodiments. The Vdd and Vss power rails 156 extend along and overlap the boundaries of the cell region with respect to the Y direction, in accordance with some embodiments.

In accordance with the embodiments of the present disclosure, the n-channel nanostructure transistors NMOSFET and the p-channel nanostructure transistors PMOSFET are formed in the same well (e.g., NW), and thus the leakage between neighboring wells with different conductivity types (e.g., n-type and p-type) may be prevented. Therefore, the performance of the resulting semiconductor device may be enhanced. In addition, the cost of the patterning process for forming the wells may be saved, and the complex design of the wells may be omitted. In some other embodiments, both the n-channel nanostructure transistors NMOSFET and the p-channel nanostructure transistors PMOSFET are formed in the p-type well.

FIG. 2 further illustrates reference cross-sections that are used in later figures. Cross-sections X1-X1 and X2-X2 are in planes parallel to the longitudinal axis (X direction) of the active regions and respectively through the active regions 104N and 104P, in accordance with some embodiments. Cross-section Y1-Y1 is in a plane parallel to the longitudinal axis (Y direction) of the final gate stack 136 and through the final gate stack 136 (or a dummy gate structure), in accordance with some embodiments. Cross-section Y2-Y2 is in a plane parallel to the longitudinal axis (Y direction) of the final gate stack 136 and across the source/drain regions of the fin structures 104, in accordance with some embodiments.

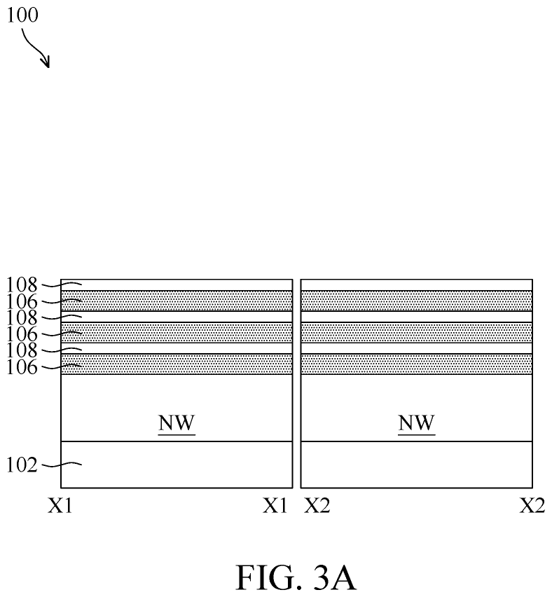

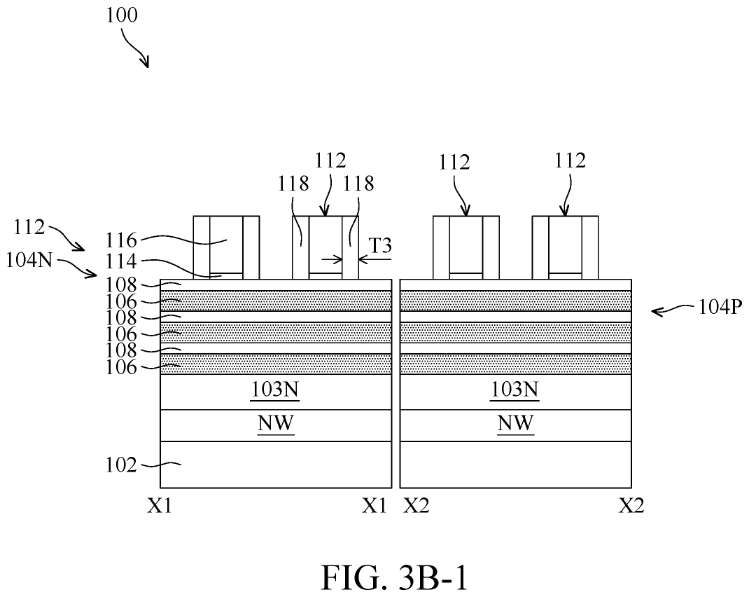

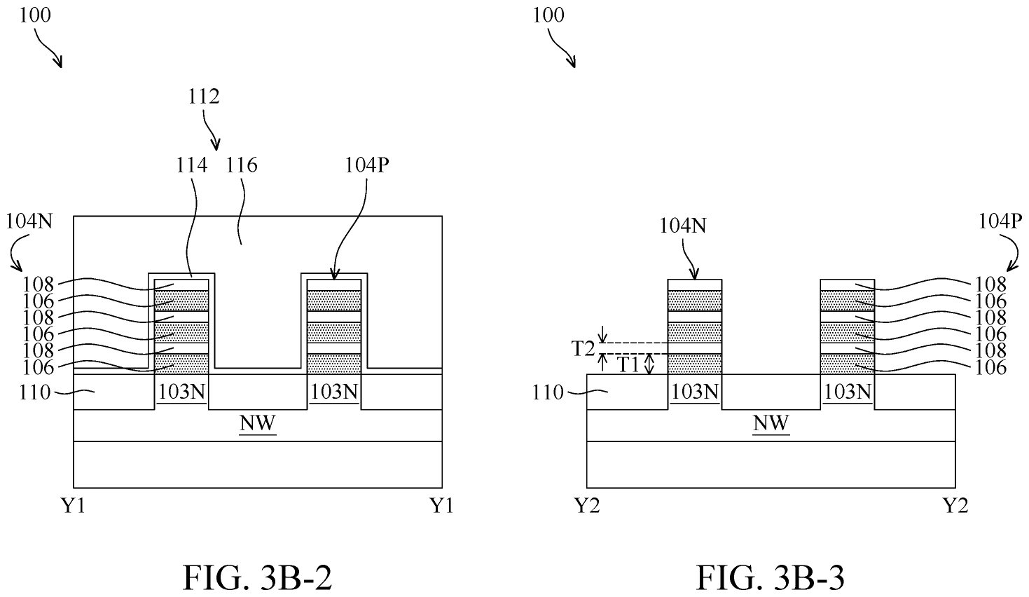

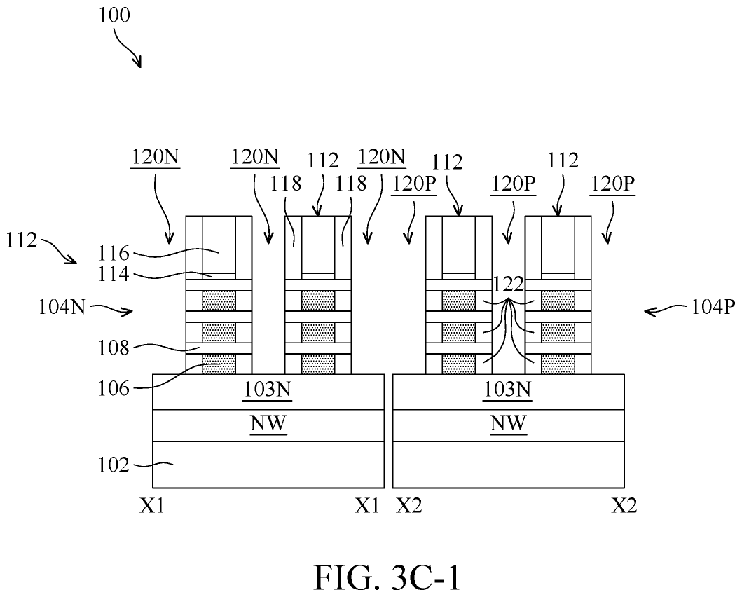

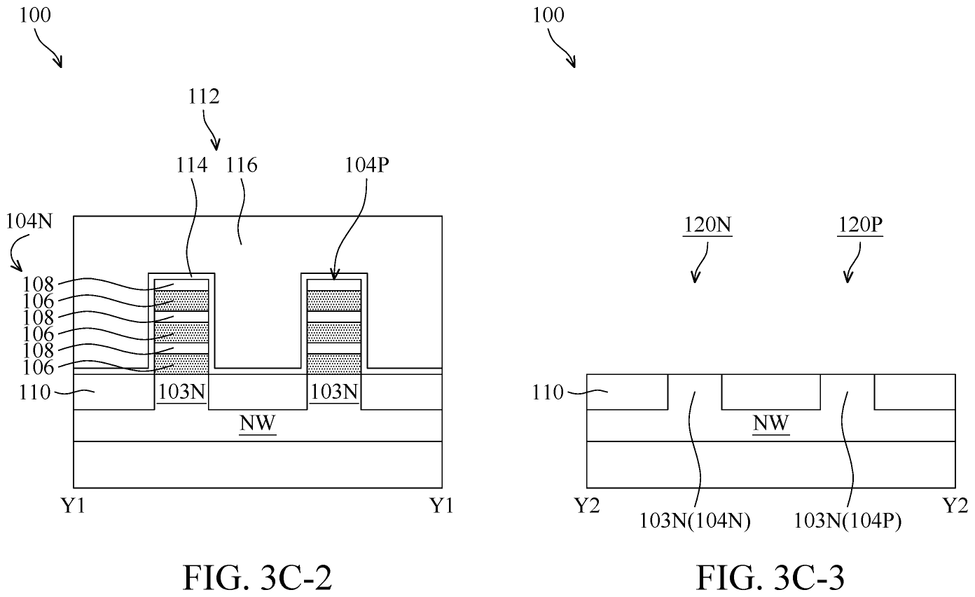

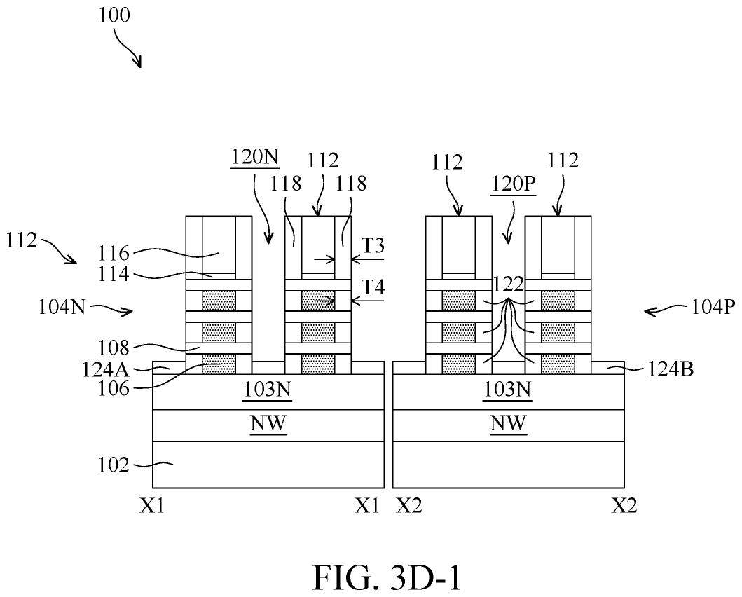

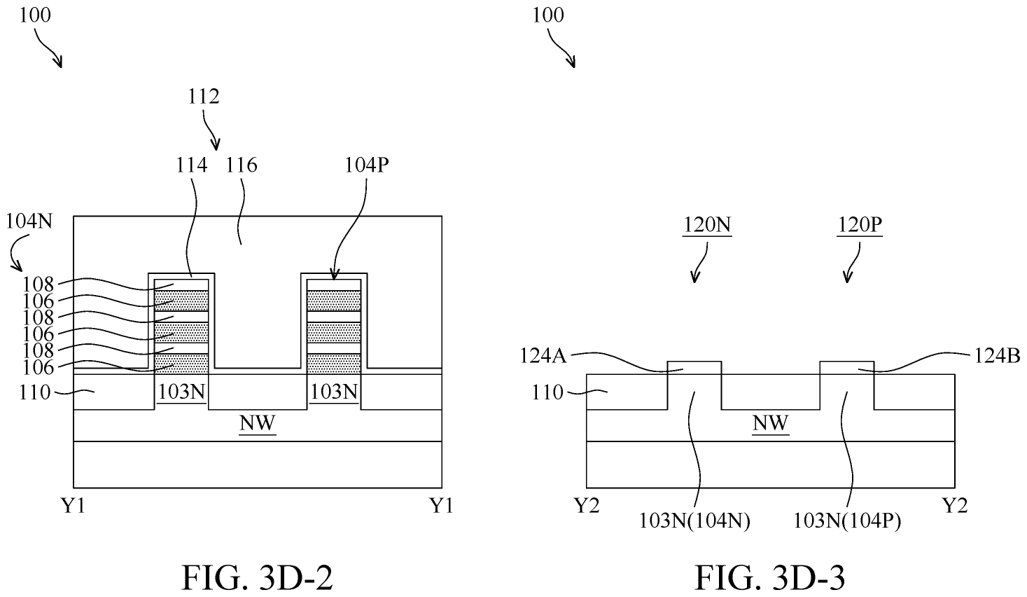

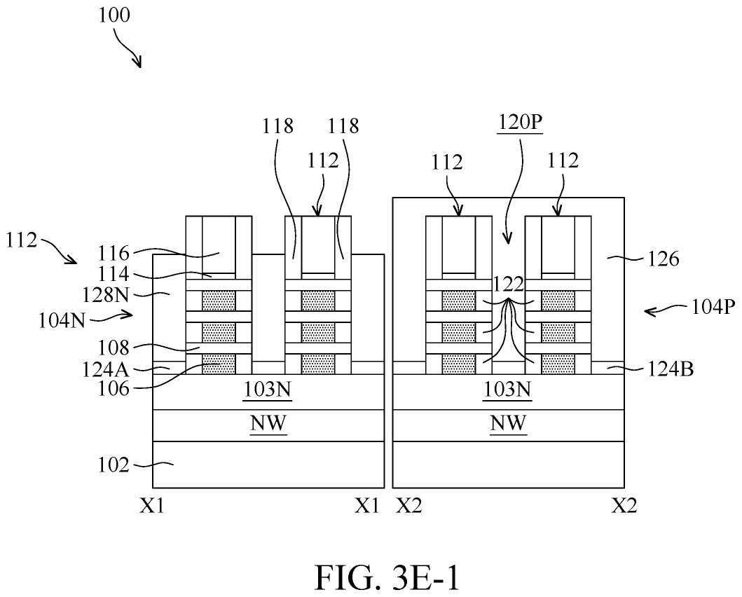

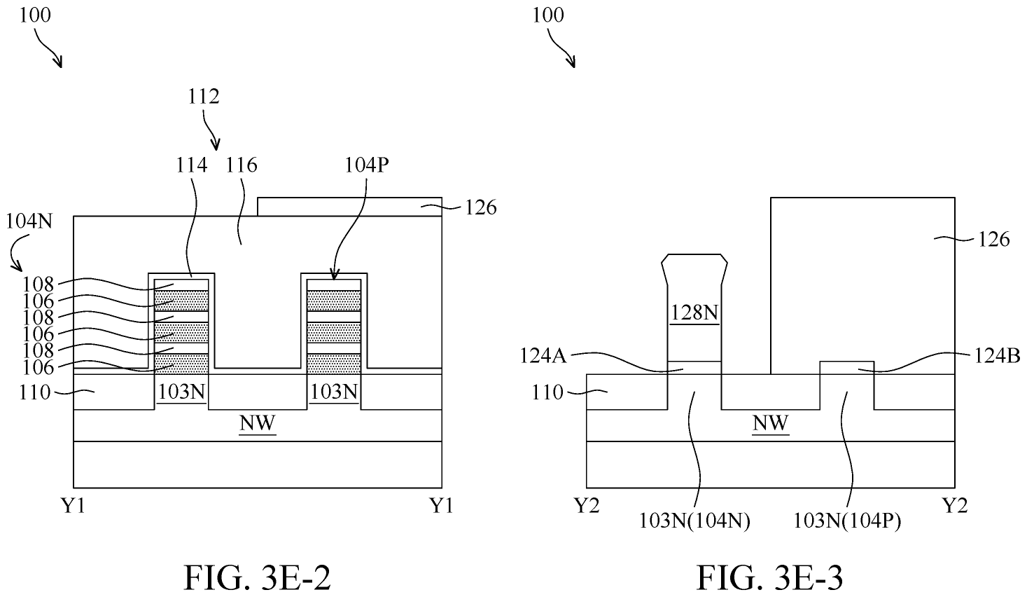

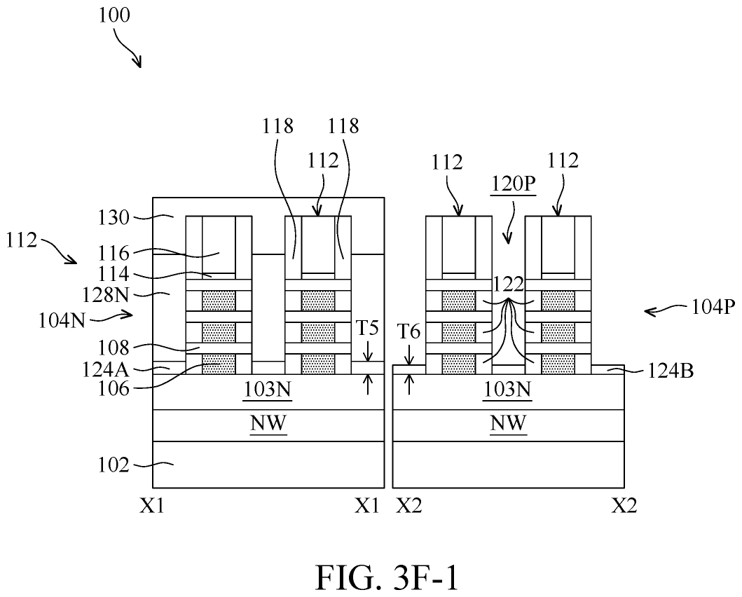

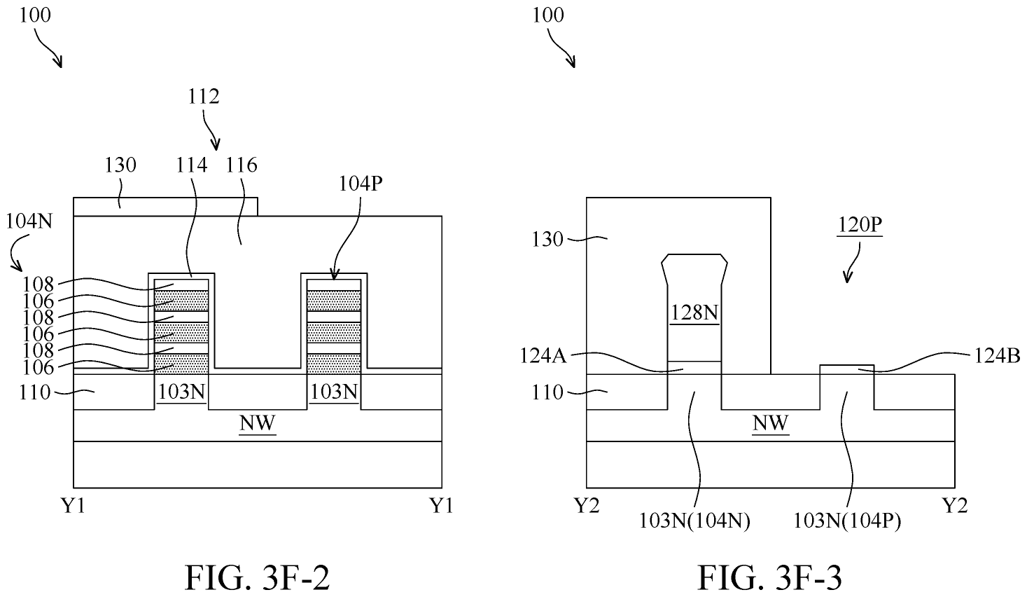

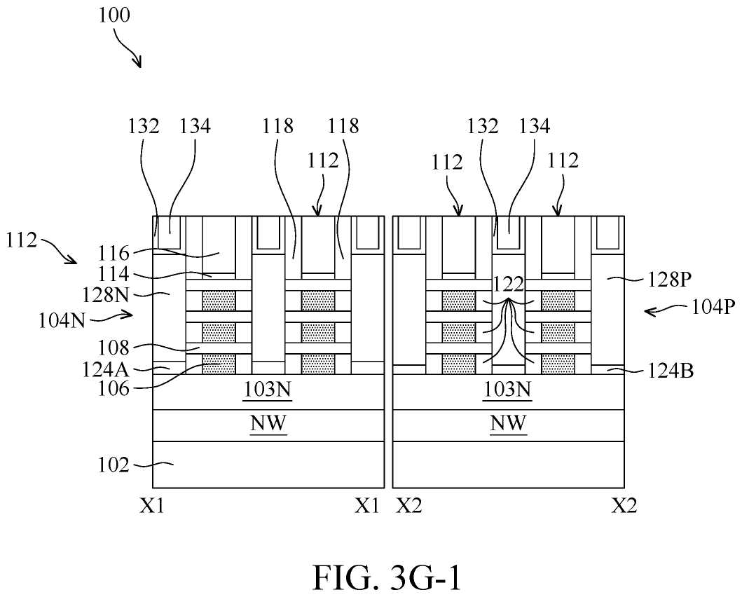

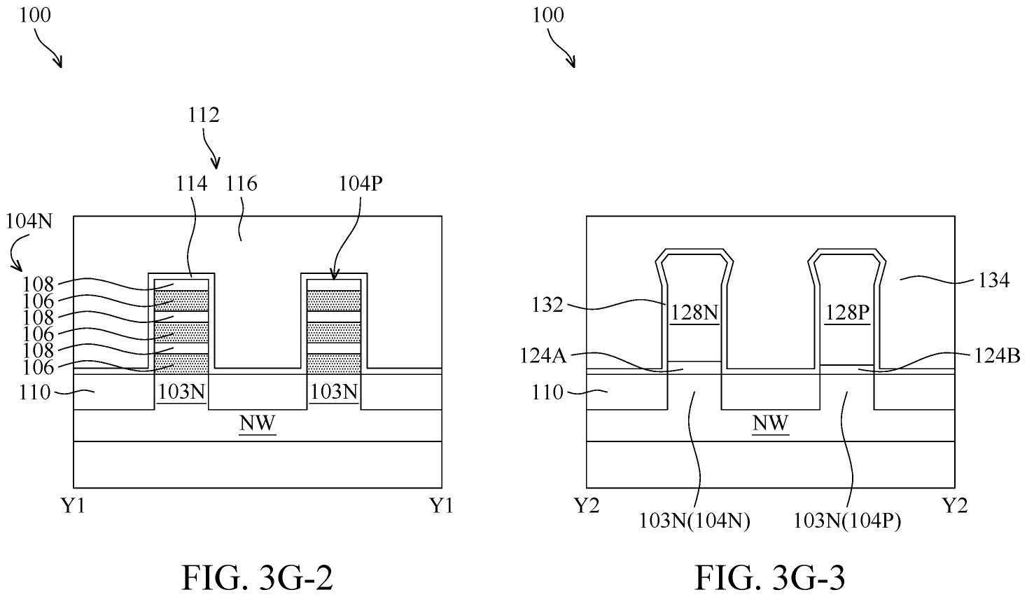

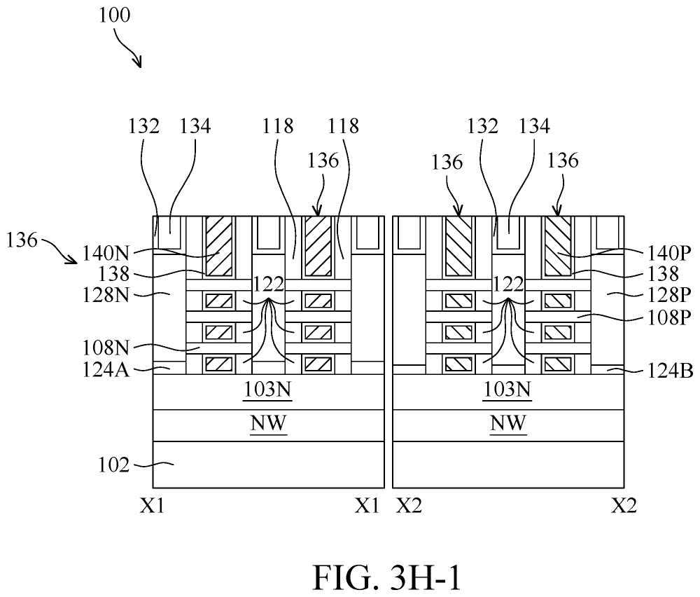

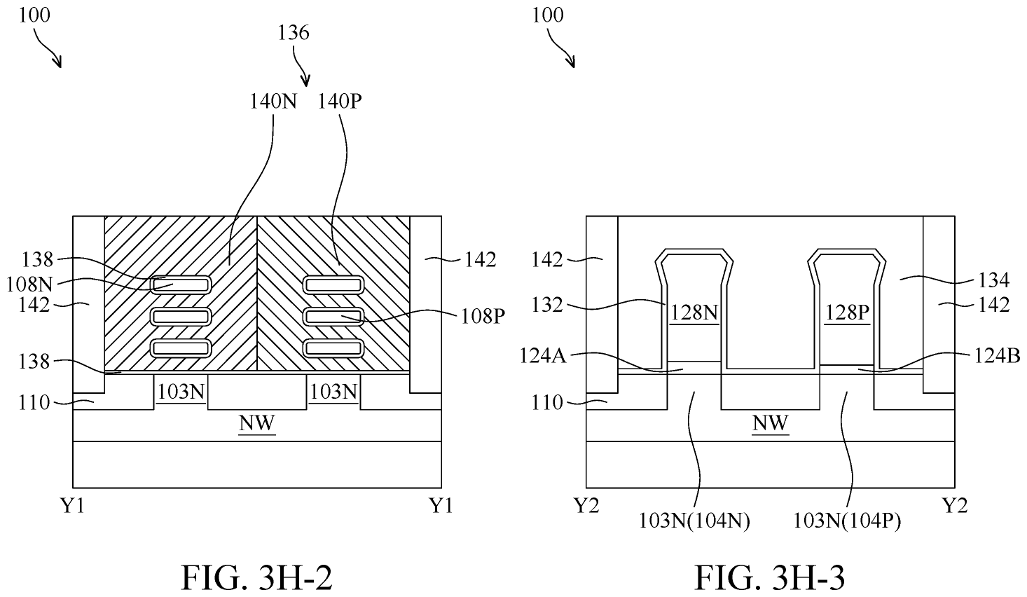

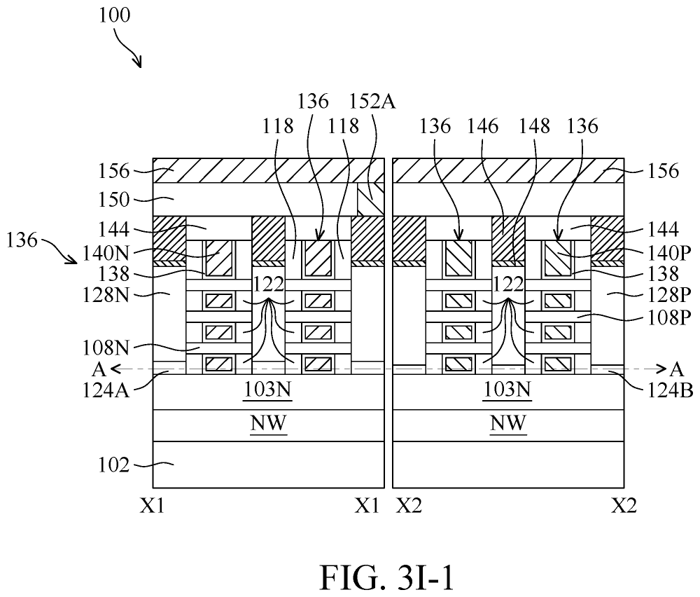

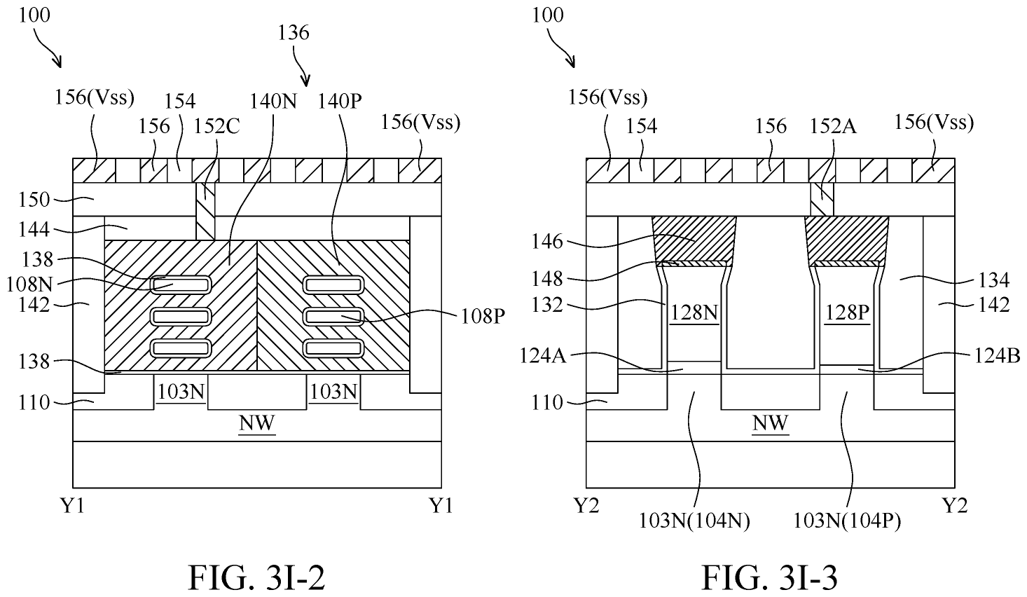

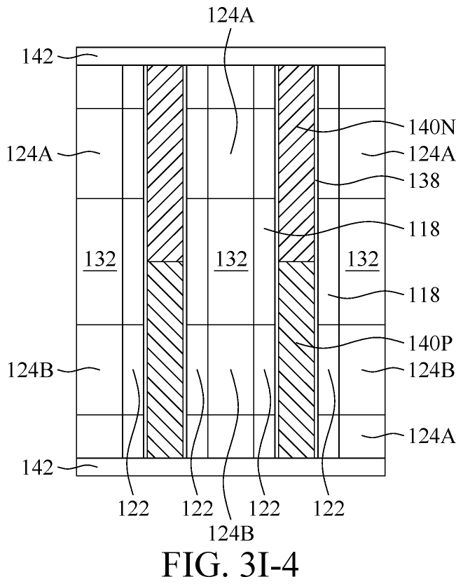

FIGS. 3A through 3I-3 are cross-sectional views illustrating the formation of a semiconductor structure 100 at various intermediate stages, in accordance with some embodiments of the disclosure.

FIG. 3A illustrates the semiconductor structure 100 after the formation of an n-type well NW and an epitaxial stack corresponding to line X1-X1 and line X2-X2.

A substrate 102 is provided, as shown in FIG. 3A-1, in accordance with some embodiments. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

An n-type well NW is formed in the substrate 102 by one or more ion implantation processes, as shown in FIG. 3A, in accordance with some embodiments. In the ion implantation process, n-type dopants (such as phosphorus or arsenic) are implanted into the substrate 102 thereby forming the n-type well NW, in accordance with some embodiments. In some embodiments, the concentration of the dopants in the n-type well NW is in a range from about 10¹⁵/cm⁻³ to about 10¹⁸/cm⁻³. In some embodiments, the ion implantation process may include anti-punch through (APT) implant. In some other embodiments, the APT implant may be omitted.

An epitaxial stack is formed over the n-type well NW using an epitaxial growth process, as shown in FIG. 3A, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{-y}Ge_{y}, where y is less than about 0.4, and x>y.

FIGS. 3B-1, 3B-2 and 3B-3 illustrate the semiconductor structure 100 after the formation of active regions 104 (including 104N and 104P), an isolation structure 110, dummy gate structures 112 and gate spacer layers 118 respectively corresponding to line X1-X1 and line X2-X2, line Y1-Y1 and line Y2-Y2.

A patterning process is performed on the epitaxial stack and the underlying n-type well NW using photolithography and an anisotropic etching process (such as dry plasma etching), thereby forming trenches and active regions 104N and 104P protruding from between trenches, in accordance with some embodiments. Both the active regions 104N and 104P are located on the n-type well NW, in accordance with some embodiments. The portion of the n-type well NW protruding from between the trenches serves as lower fin elements 103N of the active regions 104N and 104P, in accordance with some embodiments. A remainder of the epitaxial stack (including the first semiconductor layers 106 and the second semiconductor layers 108) serves as the upper fin elements of the active regions 104N and 104P, in accordance with some embodiments.

In some embodiments, each of the first semiconductor layers 106 has a thickness T1 in a range from about 4 nm to about 14 nm. In some embodiments, each of the second semiconductor layers 108 has a thickness T2 in a range from about 3 nm to about 9 nm. In some embodiments, the pitch of the second semiconductor layers 108 (e.g., the sum of thicknesses T1 and T2) is in a range from about 7 nm to about 23 nm. The thickness of the second semiconductor layers 108 may be greater than, equal to, or less than the first semiconductor layers 106, depending on the amount of gate materials to be filled in spaces where the first semiconductor layers 106 are removed.

In some embodiments, the active regions 104N and 104P extend in the X direction. That is, the active regions 104N and 104P have longitudinal axes parallel to the X direction, in accordance with some embodiments. The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments. Although three first semiconductor layers 106 and three second semiconductor layers 108 are shown in FIGS. 3B-1 to 3B-3, the number is not limited to three, and can be two or four, and is less than 10.

An isolation structure 110 is formed to surround the lower fin elements 103N of the active regions 104N and 104P, as shown in FIGS. 3B-2 and 3B-3, in accordance with some embodiments. The isolation structure 110 is configured to electrically isolate the active regions 104 of the semiconductor structure 100 and is also referred to as shallow trench isolation (STI) feature, in accordance with some embodiments.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104, in accordance with some embodiments. The planarization may be chemical mechanical polishing (CMP), etching back process, or a combination thereof. The insulating material is then recessed by an etching process (such as dry plasma etching and/or wet chemical etching) until the upper fin elements of the active regions 104 are exposed, in accordance with some embodiments.

Dummy gate structures 112 are formed across the active regions 104N and 104P, as shown in FIGS. 3B-1 and 3B-2. The dummy gate structures 112 are configured as sacrificial structures and will be replaced with the final gate stacks, in accordance with some embodiments. In some embodiments, the dummy gate structures 112 extend in the Y direction. That is, the dummy gate structures 112 have longitudinal axes parallel to the Y direction, in accordance with some embodiments. The dummy gate structures 112 surround the channel regions of the active regions 104, in accordance with some embodiments. In some embodiments, the dummy gate structures 112 are the gate structures 112 shown in FIG. 1.

Each of the dummy gate structure 112 includes a dummy gate dielectric layer 114 and a dummy gate electrode layer 116 over the dummy gate dielectric layer 114, in accordance with some embodiments. In some embodiments, the dummy gate dielectric layer 114 is conformally formed using ALD, CVD, thermal oxidation, physical vapor deposition (PVD), another suitable technique, or a combination thereof. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dummy gate electrode layer 116 is made of semiconductor material such as polysilicon or poly-silicon germanium.

In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structure 112 using photolithography and etching processes.

Gate spacer layers 118 are formed on the opposite sides of the dummy gate structure 112, as shown in FIG. 3B-1, in accordance with some embodiments. The gate spacer layers 118 are used to offset the subsequently formed source/drain features and separate the source/drain features from the gate structure, in accordance with some embodiments. In some embodiments, the gate spacer layers 118 are made of dielectric material, such as silicon-containing dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the gate spacer layers 118 may include air gaps and/or a porous version of the above-mentioned dielectric materials.

In some embodiments, the formation of the gate spacer layers 118 includes globally and conformally depositing a dielectric material for the gate spacer layers 118 over the semiconductor structure 100 using ALD, CVD (such as LPCVD, PECVD or HDP-CVD or a combination thereof, followed by an anisotropic etching process, in accordance with some embodiments. After the anisotropic etching process, the vertical portions of the dielectric material left remaining on the opposite sides of the dummy gate structure 112 form the gate spacer layers 118, in accordance with some embodiments. In some embodiments, the gate spacer layer 118 has a thickness T3 (in the X direction) in a range from about 3 nm to about 15 nm.

FIGS. 3C-1, 3C-2 and 3C-3 illustrate the semiconductor structure 100 after the formation of source/drain recesses 120N and 120P and inner spacer layers 122 respectively corresponding to line X1-X1 and line X2-X2, line Y1-Y1 and line Y2-Y2.

An etching process is performed to recess the source/drain regions of the active regions 104, thereby forming source/drain recesses 120N and 120P, as shown in FIGS. 3C-1 and 3C-2, in accordance with some embodiments. The upper fin elements are removed and the lower fin elements 103N are exposed, in accordance with some embodiments. In some embodiments, the bottom surfaces of the source/drain recesses 120N and 120P is level to the bottom surfaces of bottommost first semiconductor layers. In some other embodiments, the source/drain recesses 120N and 120P may extend a distance of about 5 nm to about 50 nm into the lower fin elements 103N and 103P. The etching process may be an anisotropic etching process such as dry plasma etching, an isotropic etching process such as dry chemical etching, remote plasma etching or wet chemical etching, or a combination thereof. The gate spacer layers 118 and the dummy gate structures 112 may serve as etch masks such that the source/drain recesses 120N and 120P are formed self-aligned opposite sides of the dummy gate structures 112, in accordance with some embodiments.

Afterward, an etching process is performed to laterally recess, from the source/drain recesses 120N and 120P, the first semiconductor layers 106 of the active regions 104N and 104P to form notches, and then inner spacer layers 122 are formed in the notches, as shown in FIG. 3C-1, in accordance with some embodiments. The inner spacer layers 122 abut the recessed side surfaces of the first semiconductor layers 106, in accordance with some embodiments. In some embodiments, the inner spacer layers 122 are located directly below the gate spacer layers 118, in accordance with some embodiments. The inner spacer layers 122 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 122 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), a multilayer thereof, or a combination thereof. In some embodiments, the inner spacer layers 122 are formed by depositing a dielectric material to overfill the notches using ALD, CVD (such as PECVD, LPCVD or HARP), and then etching away the dielectric material outside the notches using an anisotropic etching process such as dry plasma etching, an isotropic etching process such as dry chemical etching, remote plasma etching or wet chemical etching, or a combination thereof. In some embodiments, the inner spacer layers 122 have a higher dielectric constant than the gate spacer layers 118. In some embodiments, the inner spacer layers 122 have thickness T4 (in the X direction) in a range from about 1 nm to about 12 nm. In some embodiments, the thickness T3 of the gate spacer layers 118 is greater than the thickness T4 of the inner spacer layers 122 by about 0.5 nm to about 5 nm. As a result, the thicker gate spacer layer 118 may achieve good electrical isolation between the gate stack and the contact plug.

FIGS. 3D-1, 3D-2 and 3D-3 illustrate the semiconductor structure 100 after the formation of dielectric isolation features 124 respectively corresponding to line X1-X1 and line X2-X2, line Y1-Y1 and line Y2-Y2.

Dielectric isolation features 124 (including 124A and 124B) are formed in the source/drain recesses 120N and 120P on the lower fin elements 103N, as shown in FIGS. 3D-1 and 3D-3, in accordance with some embodiments. The dielectric isolation features in the source/drain recesses 120N are denoted as 124A, and the dielectric isolation features in the source/drain recesses 120P are denoted as 124B. In some embodiments, the dielectric isolation features 124A and 124B have top surfaces that are lower than the top surfaces of the bottommost semiconductor layers 108.

In some embodiments, the dielectric isolation layers 124 are made of dielectric material such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric isolation layers 124 are formed by depositing dielectric material followed by an etching-back process. In some embodiments, portions of the dielectric isolation layers 124 form along the sidewalls of the source/drain recesses 120N and 120P and the upper surface of the isolation structure 110 are removed in the etching process. In some other embodiments, the dielectric isolation layers 124 may remain on the upper surface of the isolation structure 110.

FIGS. 3E-1, 3E-2 and 3E-3 illustrate the semiconductor structure 100 after the formation of a first source/drain mask 126 and source/drain features 128N respectively corresponding to line X1-X1 and line X2-X2, line Y1-Y1 and line Y2-Y2.

A first source/drain mask 126 is formed to cover the active region 104P, as shown in FIGS. 3E-1 to 3E-3, in accordance with some embodiments. The active region 104N is exposed from the first source/drain mask 126, in accordance with some embodiments. In some embodiments, the formation of the first source/drain mask 126 includes globally and conformally depositing a hard mask layer using ALD or CVD over the semiconductor structure 100 followed by a patterning process. The hard mask layer is made of silicon-containing dielectric material such as silicon nitride (SiN), silicon oxynitride (SiON), silicon oxide (SiO₂), silicon oxynitride (SiOC), silicon carbide (SiC), or oxygen-doped silicon carbonitride (Si(O)CN); a metal oxide dielectric such as Al₂O₃, LaO, HfO₂, Ta₂O₅, TiO₂, ZrO₂, or Y₂O₃; another suitable mask material; or a combination thereof.

The patterning process may include forming a BARC material (such as an inorganic material or an organic material (e.g., polymer, oligomer, or monomer) using a spin-on coating process, a CVD process over the hard mask layer, forming a patterned photoresist layer on the BARC material corresponding to or overlapping the active region 104P using a photolithography process, and etching the BARC material and the hard mask layer using the patterned photoresist layer, in accordance with some embodiments. The photolithography process may include forming a photoresist material, performing a pre-exposure baking process, performing an exposure process using a mask (or a reticle), performing a post-exposure baking process, and performing a developing process. In some embodiments, the etching process may be an anisotropic etching process such as dry plasma etching, an isotropic etching process such as dry chemical etching, remote plasma etching, wet chemical etching, or a combination thereof. The photoresist layer and BARC material may be removed in the etching process or by additional process (e.g., etching or ashing processes).

Source/drain features 128N are formed on the second semiconductor layers 108 of the active region 104N using an epitaxial growth process, as shown in FIGS. 3E-1 and 3E-3, in accordance with some embodiments. The epitaxial growth process may be MBE, MOCVD, or VPE, another suitable technique, or a combination thereof. The source/drain features 128N fill the source/drain recesses 120N, in accordance with some embodiments. The source/drain features 128N abut the second semiconductor layers 108 of the active region 104N and the inner spacer layers 122, in accordance with some embodiments. The first source/drain mask 126 may prevent the epitaxial semiconductor material from being grown on the dielectric surface of the first source/drain mask 126, in accordance with some embodiments.

In some embodiments, the source/drain features 128N are made of semiconductor material such as SiP, SiAs, SiCP, SiC, Si, GaAs, another suitable semiconductor material, or a combination thereof. In some embodiments, the source/drain features 128N are doped with an n-type dopant during the epitaxial growth process. For example, the n-type dopant may be phosphorous (P) or arsenic (As). For example, the source/drain features 128N may be the epitaxially grown Si doped with phosphorous to form silicon:phosphor (Si:P) source/drain features and/or arsenic to form silicon:arsenic (Si:As) source/drain feature.

FIGS. 3F-1, 3F-2 and 3F-3 illustrate the semiconductor structure 100 after an etching process and the formation of a second source/drain mask 130 respectively corresponding to line X1-X1 and line X2-X2, line Y1-Y1 and line Y2-Y2.

The first source/drain mask 126 is removed using one or more etching process (e.g., a dry chemical etching, and/or a wet etching). In the etching process, the dielectric isolation features 124B are also recessed and thus thinned down, e.g., by an over-etch step. A second source/drain mask 130 is formed to cover the active region 104N and the source/drain features 128N, as shown in FIGS. 3F-1 to 3F-3, in accordance with some embodiments. The active region 104P is exposed from the second source/drain mask 130, in accordance with some embodiments.

In some embodiments, the formation of the second source/drain mask 130 includes globally and conformally depositing a hard mask layer using ALD or CVD over the semiconductor structure 100 followed by a patterning process. The hard mask layer is made of silicon-containing dielectric material such as silicon nitride (SiN), silicon oxynitride (SiON), silicon oxide (SiO₂), silicon oxynitride (SiOC), silicon carbide (SiC), or oxygen-doped silicon carbonitride (Si(O)CN); a metal oxide dielectric such as Al₂O₃, LaO, HfO₂, Ta₂O₅, TiO₂, ZrO₂, or Y₂O₃; another suitable mask material; or a combination thereof.

The patterning process may include forming a BARC material (such as an inorganic material or an organic material (e.g., polymer, oligomer, or monomer) using a spin-on coating process, a CVD process over the hard mask layer, forming a patterned photoresist layer on the BARC material corresponding to or overlapping the active region 104N using a photolithography process as described above, and etching the BARC material and the hard mask layer using the patterned photoresist layer, in accordance with some embodiments.

In the etching process for forming the second source/drain mask 130, the dielectric isolation features 124B are also recessed and thus thinned down. As a result, the dielectric isolation features 124A are thicker than the dielectric isolation features 124B by about 0.5 nm to about 5 nm. The thickness T5 of the dielectric isolation features 124A is in a range from about 1 nm to about 20 nm, e.g., about 1.5 nm to about 10 nm. The thickness T6 of the dielectric isolation features 124B is in a range from about 1 nm to about 20 nm, e.g., about 1.5 nm to about 10 nm. If the dielectric isolation features 124A/B are too thick, the sidewalls of the bottommost second semiconductor layers may be covered. If the dielectric isolation features 124A/B are too thin, the isolation capability of the dielectric isolation features 124A/B may be insufficient, which may be described in detail later.

FIGS. 3G-1, 3G-2 and 3G-3 illustrate the semiconductor structure 100 after the formation of source/drain features 128P, a contact etching stop layer 132 and a first interlayer dielectric layer 134 respectively corresponding to line X1-X1 and line X2-X2, line Y1-Y1 and line Y2-Y2.

Source/drain features 128P are formed on the second semiconductor layers 108 of the active region 104P using an epitaxial growth process, as shown in FIGS. 3G-1 and 3G-3, in accordance with some embodiments. The epitaxial growth process may be MBE, MOCVD, or VPE, another suitable technique, or a combination thereof. The source/drain features 128P fill the source/drain recesses 120P, in accordance with some embodiments. The source/drain features 128P abut the second semiconductor layers 108 of the active region 104P and the inner spacer layers 122, in accordance with some embodiments. The second source/drain mask 130 may prevent the epitaxial semiconductor material from being grown on the dielectric surface of the second source/drain mask 130, in accordance with some embodiments. Afterwards, the second source/drain mask 130 is removed using an etching process (e.g., a dry chemical etching, and/or a wet etching).

In some embodiments, the source/drain features 128P are made of semiconductor material such as SiGe, Si, GaAs, another suitable semiconductor material, or a combination thereof. In some embodiments, the source/drain features 128P are doped with a p-type dopant during the epitaxial growth process. For example, the p-type dopant may be boron (B) or BF₂. For example, the source/drain features 128P may be the epitaxially grown SiGe doped with boron (B) to form silicon germanium:boron (SiGe:B) source/drain feature.

In some embodiments, the concentration of the dopant in the source/drain features 128N in a range from about 2×10¹⁹ cm⁻³ to about 3×10²¹ cm⁻³, and the concentration of the dopant in the source/drain features 128P in a range from about 1×10¹⁹ cm⁻³ to about 6×10²⁰ cm⁻³. An annealing process may be performed on the semiconductor structure 100 to activate the dopants in the source/drain features 128N and 128P, in accordance with some embodiments.

In some embodiments, the n-type source/drain features 128N and the p-type source/drain features 128P are made of different epitaxial materials. For example, the n-type source/drain features 128N are made of SiP, and the p-type source/drain features 128P are made of SiGe.

A contact etching stop layer 132 is formed over the semiconductor structure 100 to cover the source/drain features 128N and 128P, as shown in FIGS. 3G-1 and 3G-3, in accordance with some embodiments. In some embodiments, the contact etching stop layer 132 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 132 is globally and conformally deposited over the semiconductor structure 100 using CVD (such as LPCVD, PECVD, HDP-CVD, or HARP), ALD, another suitable method, or a combination thereof.

A first interlayer dielectric layer 134 is formed over the contact etching stop layer 132, as shown in FIGS. 3G-1 and 3G-3, in accordance with some embodiments. In some embodiments, the first interlayer dielectric layer 134 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the first interlayer dielectric layer 134 and the contact etching stop layer 132 are made of different materials and have a great difference in etching selectivity. In some embodiments, the dielectric material for the first interlayer dielectric layer 134 is deposited using such as CVD (such as HDP-CVD, PECVD, HARP or FCVD), another suitable technique, or a combination thereof.

The dielectric materials for the contact etching stop layer 132 and the first interlayer dielectric layer 134 above the upper surface of the dummy gate electrode layer 116 are removed using such as CMP, in accordance with some embodiments.

FIGS. 3H-1, 3H-2 and 3H-3 illustrate the semiconductor structure 100 after final gate stacks 136 and gate-cut structures 142 respectively corresponding to line X1-X1 and line X2-X2, line Y1-Y1 and line Y2-Y2.

One or more etching processes are performed to remove the dummy gate structures 112 to form gate trenches and remove the first semiconductor layers 106 of the active regions 104N and 104P to form gaps, in accordance with some embodiments. In some embodiments, the gate trenches expose the channel regions of the active regions 104N and 104P. In some embodiments, the gate trenches further expose the sidewalls of the gate spacer layers 118 facing the channel region. In some embodiments, the gaps expose the inner sidewalls of the inner spacer layers 122 facing the channel region. The one or more etching processes may include an anisotropic etching process such as dry plasma etching, an isotropic etching process such as dry chemical etching, remote plasma etching or wet chemical etching, or a combination thereof.

After the one or more etching processes, the four main surfaces of the second semiconductor layers 108 are exposed, in accordance with some embodiments. The exposed second semiconductor layers 108 of the active region 104N form nanostructures 108N, and the exposed second semiconductor layers 108 of the active region 104P form nanostructures 108P, as shown in FIGS. 3H-1 and 3H-2, in accordance with some embodiments. The nanostructures 108N and 108P which are vertically stacked function as a set of channel layers for a transistor, in accordance with some embodiments. As the term is used herein, “nanostructures” refers to the semiconductor layers with cylindrical shape, bar shaped and/or sheet shape.

Final gate stacks 136 are formed in the gate trenches and gaps, thereby wrapping around the nanostructures 108N and 108P, as shown in FIGS. 3H-1 and 3H-2, in accordance with some embodiments. In some embodiments, the final gate stacks 136 extend in the Y direction. The final gate stacks 136 engage the channel region so that current can flow between the source/drain regions during operation. In some embodiments, each of the final gate stacks 136 includes a gate dielectric layer 138 and a metal gate electrode layer.

The gate dielectric layer 138 is formed to wrap around the nanostructures 108N and 108P, in accordance with some embodiments. The gate dielectric layer 138 is further formed along the upper surface of the isolation structure 110, in accordance with some embodiments. The gate dielectric layer 138 is also conformally formed along the sidewalls of the gate spacer layers 118 and the inner spacer layers 122 facing the channel region, in accordance with some embodiments.

The gate dielectric layer 138 includes an interfacial layer and a high-k dielectric layer on the interfacial layer, in accordance with some embodiments. The interfacial layer is formed on the exposed surfaces of the nanostructures 108N and 108P and the exposed upper surfaces of the lower fin elements 103N and 103P, in accordance with some embodiments. In some embodiments, the interfacial layer is made of a chemically formed silicon oxide, which is formed using one or more cleaning processes. In some embodiments, the interfacial layer may be a nitrogen-doped silicon oxide layer. In some embodiments, the high-k dielectric layer is dielectric material with high dielectric constant (k value), for example, greater than 7.9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Si₃N₄, oxynitrides (SiON), a combination thereof, or another suitable material. The high-k dielectric layer may be deposited using ALD, PVD, CVD, and/or another suitable technique.

The metal gate electrode layer is formed to fill remainders of the gate trenches, in accordance with some embodiments. The metal gate electrode layer includes an n-type work function metal material 140N surrounding the nanostructures 108N and a p-type work function metal material 140P surrounding the nanostructures 108P, in accordance with some embodiments. In some embodiments, the work function metal materials 140N and 140P have selected work functions to enhance the device performance (e.g., threshold voltage) for n-channel FETs or p-channel FETs. The work function metal materials 140N and 140P may be formed separately.

In some embodiments, the work function metal materials 140N and 140P are made of more than one conductive material, such as TiN, TaN, TiAl, TiAlN, TaAl, TaAlN, TaAlC, TaCN, WNC, Co, Pt, W, Ti, Ag, Al, TaC, TaSiN, Mn, Zr, Ru, Mo, WN, Cu, W, Re, Ir, Ni, another suitable conductive material, or multilayers thereof. The work function metal material 140N includes a different combination of materials than the work function metal material 140P, in accordance with some embodiments. The work function metal materials 140N and 140P may be formed using ALD, PVD, CVD, e-beam evaporation, or another suitable technique.

A planarization process such as CMP may be performed on the semiconductor structure 100 to remove the materials of the gate dielectric layer 138 and the metal gate electrode layer formed above the first interlayer dielectric layer 136, in accordance with some embodiments.

The final gate stacks 136 that are wrapped around the nanostructures 108N combine with the neighboring source/drain features 122N to form the n-channel nanostructure transistors (e.g., NMOSFET shown in FIG. 2), in accordance with some embodiments. The final gate stacks 136 that are wrapped around the nanostructures 108P combine with the neighboring source/drain features 122P to form the p-channel nanostructure transistors (e.g., PMOSFET shown in FIG. 2), in accordance with some embodiments.

Gate-cut structures 142 are formed through the final gate stacks 136 and the gate spacer layers 118, the contact etching stop layer 132 and the first interlayer dielectric layer 134, as shown in FIGS. 3H-2 and 3H-3, in accordance with some embodiments. In some embodiments, the gate-cut structures 142 extend in the X direction. The final gate stacks 136 are cut through by the gate-cut structures 142 into several segments which are physically and electrically isolated from each other, in accordance with some embodiments. The gate-cut structures 142 may be also referred to as cut metal gate (CMG) pattern.

The gate-cut structures 142 are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the gate-cut structures 142 include dielectric material with a dielectric constant value greater than 7.9, such as LaO, AlO, AlON, ZrO, HfO, ZnO, ZrN, ZrAlO, TiO, TaO, YO, TaCN, or a combination thereof. The formation of the gate-cut structures 142 includes patterning the semiconductor structure 100 to form gate-cut openings using photolithography and etching processes, depositing a dielectric material to overfill the gate-cut openings, in accordance with some embodiments. A planarization process (e.g., CMP, etching back process, or a combination thereof) is then performed on the dielectric material until the first interlayer dielectric layer 134 is exposed, in accordance with some embodiments.

FIGS. 3I-1, 3I-2 and 3I-3 illustrate the semiconductor structure 100 after the formation of dielectric cap layers 144, contact plugs 146, a second interlayer dielectric layer 150, vias 152A, 152B and 152C, an intermetal dielectric layer 154, and a first-level metal layer (M1), in accordance with some embodiments.

An etching process is performed to recess the final gate stacks 136 and the gate spacer layers 118 thereby forming recesses, and then dielectric cap layers 144 are formed in the recesses, as shown in FIGS. 3I-1 and 3I-2, in accordance with some embodiments.

The etching process may be an anisotropic etching process such as dry plasma etching, an isotropic etching process such as dry chemical etching, remote plasma etching or wet chemical etching, and/or a combination thereof. In some embodiments, the dielectric cap layers 144 are made of dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), nitride-based dielectric, metal oxide dielectric such as HfO₂, Ta₂O₅), TiO₂, ZrO₂, Al₂O₃, Y₂O₃, or a combination thereof.

In some embodiments, a dielectric material for the dielectric cap layers 144 is deposited using such as ALD, CVD (such as LPCVD, PECVD, HDP-CVD, or HARP), another suitable technique, and/or a combination thereof. Afterward, a planarization process (such as CMP or an etching back process) is performed on the dielectric material until the first interlayer dielectric layer 134 is exposed, in accordance with some embodiments.

Contact plugs 146 are formed through the first interlayer dielectric layer 134 and the contact etching stop layer 132 and land on the source/drain features 128N and 128P, as shown in FIGS. 3I-1 and 3I-3, in accordance with some embodiments. The contact plugs 146 are electrically connected to the source/drain features 128N and 128P, in accordance with some embodiments. In some embodiments, the formation of the contact plugs 146 includes patterning the first interlayer dielectric layer 134 and the contact etching stop layer 132 to form contact openings using photolithography and etching processes until the source/drain features 128 are exposed. In some embodiments, the portions of the contact etching stop layer 132 formed along the gate spacer layers 118 are entirely removed, thereby exposing the sidewalls of the gate spacer layers 118. In some other embodiments, the gate spacer layers 118 may remain covered by the contact etching stop layer 132 after the etching process for forming the contact openings.

Silicide layers 148 are formed on the exposed surfaces of the source/drain features 122N and 122P, in accordance with some embodiments. In some embodiments, the silicide layers 148 are made of WSi, NiSi, TiSi and/or CoSi. In some embodiments, the formation of the silicide layers 148 includes depositing a metal material followed by one or more annealing processes. The semiconductive material (e.g., Si) from the source/drain features 128N and 128P reacts with the metal material to form the silicide layers 148, in accordance with some embodiments. Unreacted metal material is then removed, e.g., using wet etching. Afterward, one or more conductive materials for the contact plugs 146 are deposited using CVD, PVD, e-beam evaporation, ALD, ECP, ELD, another suitable method, or a combination thereof to overfill the contact openings, in accordance with some embodiments. The one or more conductive materials over the first interlayer dielectric layer 134 are planarized using, for example, CMP.

The contact plugs 146 may have a multilayer structure. For example, a barrier/adhesive layer (not shown) may optionally be deposited along the sidewalls and the bottom surfaces of the contact openings. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

A second interlayer dielectric layer 150 is formed over the semiconductor structure 100, as shown in FIGS. 3I-1 to 3I-3, in accordance with some embodiments. In some embodiments, the second interlayer dielectric layer 150 is made of dielectric material, such as USG, BPSG, FSG, PSG, BSG, and/or another suitable dielectric material. In some embodiments, the second interlayer dielectric layer 150 is deposited using such as CVD (such as HDP-CVD, PECVD, HARP or FCVD), another suitable technique, or a combination thereof.

Vias 152A (and 152B) and are formed through the second interlayer dielectric layer 150 and land on the contact plugs 146, and vias 152C are formed through the second interlayer dielectric layer 150 and the dielectric capping layer 146 and land on the metal gate electrode layer of the final gate stacks 136, as shown in FIGS. 3I-1 to 3I-3, in accordance with some embodiments. The vias 152C are electrically connected to the final gate stacks 136 and may be also referred to as gate vias (VG), in accordance with some embodiments. The vias 152A and 152B are electrically connected to source/drain terminals of the nanostructure transistors through the contact plugs 146 and may be also referred to as source/drain vias (VS or VD), in accordance with some embodiments.

In some embodiments, the formation of the vias 152A, 152B and 152C includes patterning the semiconductor structure 100 to form via openings using photolithography and etching processes. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the second interlayer dielectric layer 150 are planarized using, for example, CMP.

The vias 152A, 152B and 152C may have a multilayer structure, for example, including a barrier/adhesive layer and a metal bulk layer. The barrier layer may be made of Ta, TaN, Ti, TiN, CoW, another suitable material, or a combination thereof. In some embodiments, the metal bulk layer is made of one or more conductive materials, such as Co, Ni, W, Ti, Ta, Cu, Rh, Ir, Pt, Al, Ru, Mo, or a combination thereof.

A first intermetal dielectric layer 154 is formed over the vias 152A, 152B and 152C and the second interlayer dielectric layer 150, and lines 156 of a first-level metal layer (M1) are formed through the first intermetal dielectric layer 154, as shown in FIGS. 3I-1 to 3I-3, in accordance with some embodiments. The lines 156 extend in the X direction, in accordance with some embodiments.

In some embodiments, the first intermetal dielectric layer 154 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof. In some embodiments, the first intermetal dielectric layer 154 is made of an extremely low-k (ELK) dielectric material with a dielectric constant (k) less than about 3.0, or even less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SILK, or porous silicon oxide (SiO₂). In some embodiments, the first intermetal dielectric layer 154 is formed using CVD (such as LPCVD, HARP, and FCVD), ALD, spin-on coating, another suitable method, or a combination thereof. A post-curing process (e.g., UV curing) may be performed on the as-deposited ELK dielectric material for the first intermetal dielectric layer 154 to form a porous structure.

In some embodiments, the formation of the metal lines 156 includes patterning the semiconductor structure 100 to form trenches using photolithography and etching processes. Afterward, one or more conductive materials are deposited using CVD, PVD, e-beam evaporation, ALD, ECP, ELD, another suitable method, or a combination thereof to overfill the trenches, in accordance with some embodiments. The one or more conductive materials over the upper surface of the first intermetal dielectric layer 154 are planarized using, for example, CMP. The lines 156 may have a multilayer structure, for example, including a barrier/adhesive layer and a metal bulk layer. The barrier layer may be made of Ta, TaN, Ti, TiN, CoW, another suitable material, or a combination thereof. In some embodiments, the metal bulk layer is made of one or more conductive materials, such as Co, Ni, W, Ti, Ta, Cu, Rh, Ir, Pt, Al, Ru, Mo, or a combination thereof.

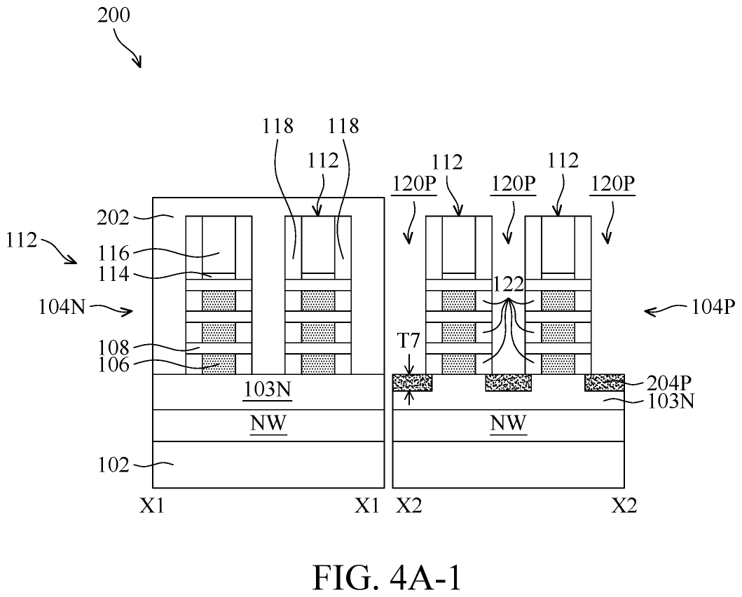

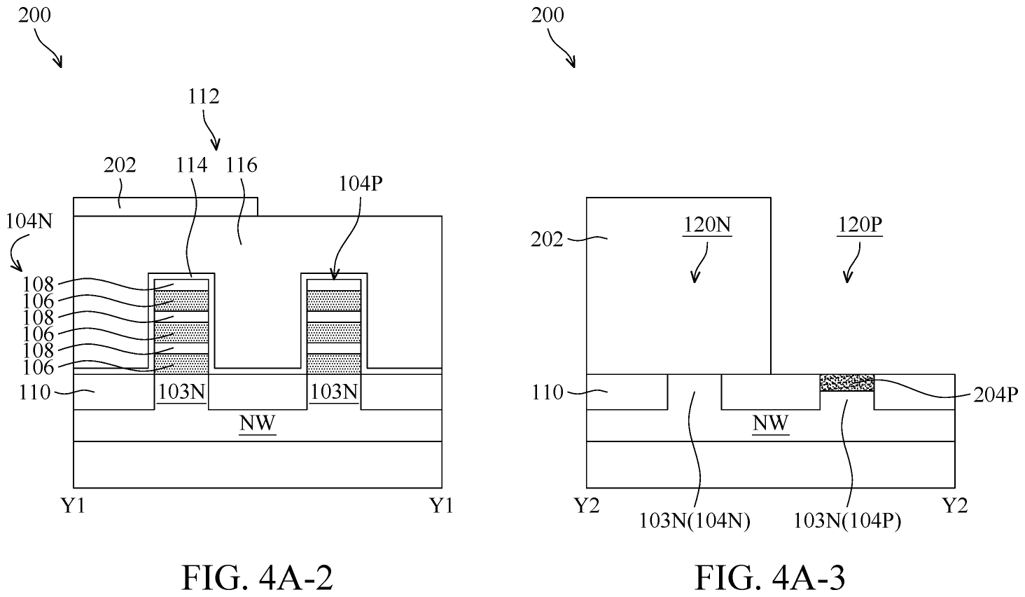

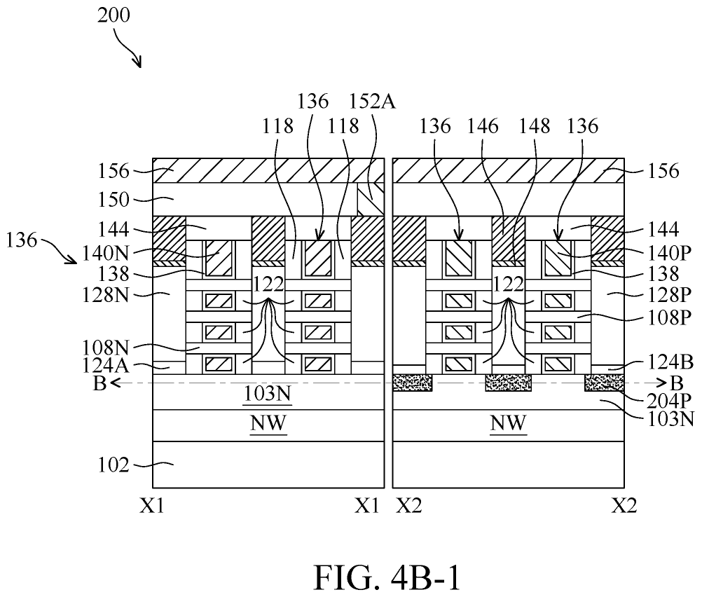

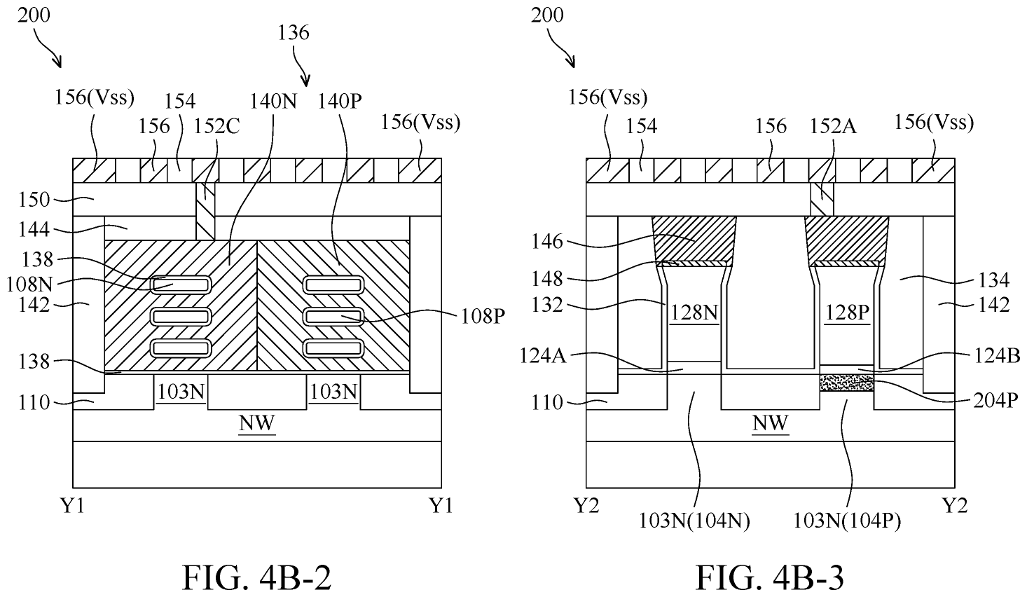

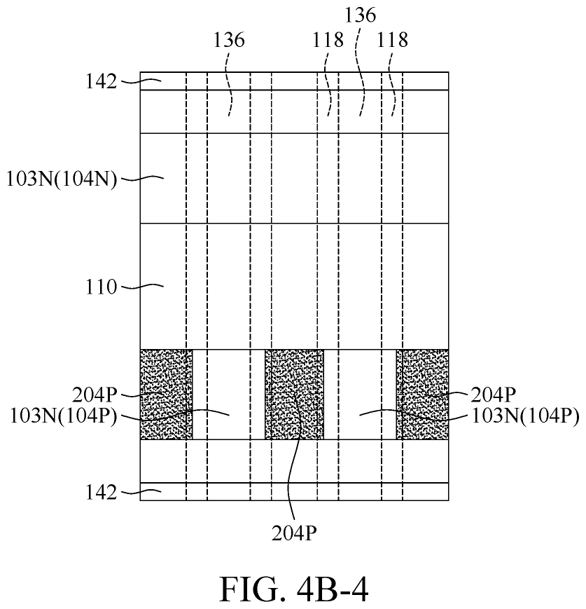

FIG. 3I-4 is a plan view illustrating the semiconductor of FIG. 3I-1 taken along plane A-A, in accordance with some embodiments of the disclosure. In some embodiments, the dielectric isolation features 124A/B are defined between the inner spacer layers 122. In some embodiments, the sidewalls of the dielectric isolation features 124A/B interfaced with the contact etching stop layer 132 are substantially aligned with the sidewalls of the inner spacer layers 122 interfaced with the gate spacer layers 118.

In the embodiments of the present disclosure, the formation of the dielectric isolation features 124A/B may block the leakage path of the bottom planar transistor. Furthermore, because the n-channel nanostructure transistors (NMOSFET) are formed in the n-type well NW instead of in the p-type well, the dielectric isolation features 124A with a greater thickness T5 is required to sufficiently isolate the source/drain feature 128N from the lower fin elements 103N. Therefore, the leakage issue of the body-to-gate interface region may be significantly reduced, thereby enhancing the performance (e.g., Isoff) of the resulting semiconductor device.

In addition, the dielectric isolation features 124A/B between the source/drain features 128N/P and the lower fin element 103N may dramatically reduce both the parasitic capacitances between the gate stack 136 and the source/drain features 128N/P and the parasitic capacitances between the source/drain features 128N/P and the well NW, in accordance with some embodiments. Therefore, the performance (e.g., speed) of the resulting semiconductor device may be enhanced.

In addition, the semiconductor device of the present disclosure with the leakage proof components (e.g., the dielectric isolation features 124A/B) may allow for lower APT doses, or alternatively may allow for APT-free (skip) scheme. This may eliminate the effect of APT dose out-diffusion, thereby improving the threshold (Vt) mismatch issue of the resulting semiconductor device.

It should be understood that the semiconductor structure 100 may undergo further CMOS processes to form various features over the semiconductor structure 100, such as a multilayer interconnect structure (e.g., metal lines, inter metal dielectric layers, passivation layers, etc.).

FIGS. 4A-1 through 4B-3 are cross-sectional views illustrating the formation of a semiconductor structure 200 at various intermediate stages, in accordance with some embodiments of the disclosure. The embodiments of FIGS. 4A-1 through 4B-3 are similar to the embodiments of FIGS. 3A through 3I-3 except that doped regions 204P are formed under the dielectric isolation features 124A/B.

FIGS. 4A-1, 4A-2 and 4A-3 illustrate the semiconductor structure 200 after an implantation process respectively corresponding to line X1-X1 and line X2-X2, line Y1-Y1 and line Y2-Y2.

Once the inner spacer layers 122 are formed, a patterned mask layer 202 is formed to cover the active regions 104N, and an implantation process is performed on the semiconductor structure 200 to form doped regions 204P in the lower fin element 103N of the active regions 104P, as shown in FIGS. 4A-1 and 4A-3, in accordance with some embodiments. The patterned mask layer 202 may be a patterned mask layer and/or a patterned photoresist layer, which may be formed by the method described above.

The implantation process may be performed using a high-current ion implanter, or the like. In the implantation process, p-type dopants (e.g., boron (B) or BF₂) are introduced through the source/drain recess 120P using various ion species that are ionized and accelerated to inject into the lower fin element 103N of the active regions 104P, in accordance with some embodiments. In some embodiments, the thickness T7 of the doped region 204P is in a range from about 3 nm to about 30 nm. In some embodiments, the concentration of the dopants in the doped region 204P is in a range from about 10¹⁷/cm⁻³ to about 10¹⁹/cm⁻³. In some embodiments, the concentration of doped region 204P is higher than the concentration of the lower fin element 103N (or the n-type well NW)

Because the p-type doped region 204P have a different conductivity type than the lower fin element 103N, a P-N junction is formed between the p-type doped region 204P and the lower fin element 103N, in accordance with some embodiment. The doped regions 204P extend directly under the inner spacer layers 122 (or the gate spacer layers 118), in accordance with some embodiment.

FIGS. 4B-1, 4B-2 and 4B-3 illustrate the semiconductor structure 200 after the formation of nanostructure transistors, contact plugs 146, vias 152A, 152B and 152C, and the first-level metal layer (M1) respectively corresponding to line X1-X1 and line X2-X2, line Y1-Y1 and line Y2-Y2.

The patterned mask layer 202 is removed using an etching process (e.g., a dry chemical etching, and/or a wet etching). Afterward, the steps described above in FIGS. 3D-1 to 3I-3 are performed, thereby forming dielectric isolation features 124A and 124B, source/drain features 128N and 128P, a contact etching stop layer 132, a first interlayer dielectric layer 134, final gate stacks 136, gat-cut structures 142, dielectric cap layer 144, contact plugs 146, second interlayer dielectric layer 150, vias 152A, 152B and 152C, a first intermetal dielectric layer 154 and metal lines 156, as shown in FIGS. 4B-1, 4B-2 and 4B-3, in accordance with some embodiments. In some embodiments, the dielectric isolation features 124B are formed on the doped regions 204P. In some embodiments, the doped regions 204P are wider than the dielectric isolation features 124B in the X direction, as shown in FIG. 4B-1.

FIG. 4B-4 is a plan view illustrating the semiconductor of FIG. 4B-1 taken along plane B-B, in accordance with some embodiments of the disclosure. In some embodiments, the gate spacer layers 118 (or the inner spacer layers 122) overlap the edge of the p-type doped region 204P (or the P-N junction formed between the p-type doped region 204P and the lower fin element 103N).

Because the etching processes (e.g., removal of the first source/drain mask 126 and/or formation of the second source/drain mask 130) performed on the dielectric isolation features 124B may cause them to become damaged or broken, the isolation between the source/drain features 128P and lower fin element 103N may no longer be robust. In the embodiments of the present disclosure, the P-N junction formed between the p-type doped region 204P and the lower fin element 103N may prevent such a potential leakage path. In addition, the doped regions 204P encompass the dielectric isolation features 124B, and thus the leakage path may be adequately blocked even if the dielectric isolation features 124B is broken.

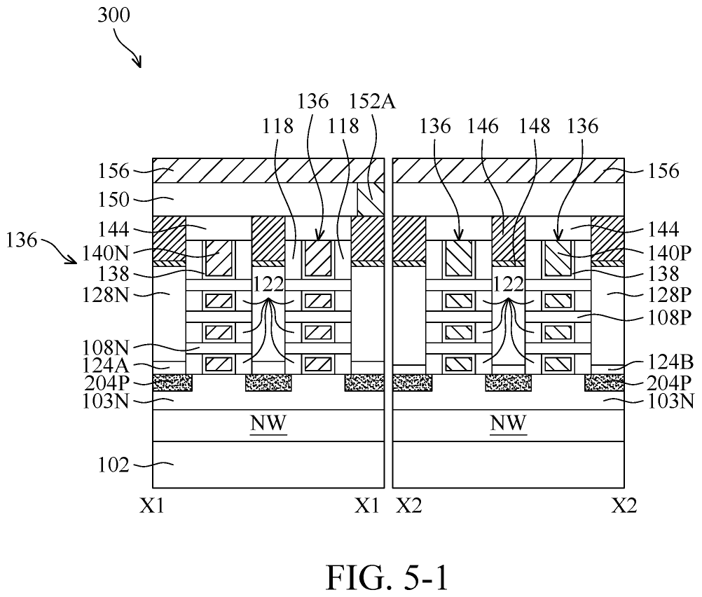

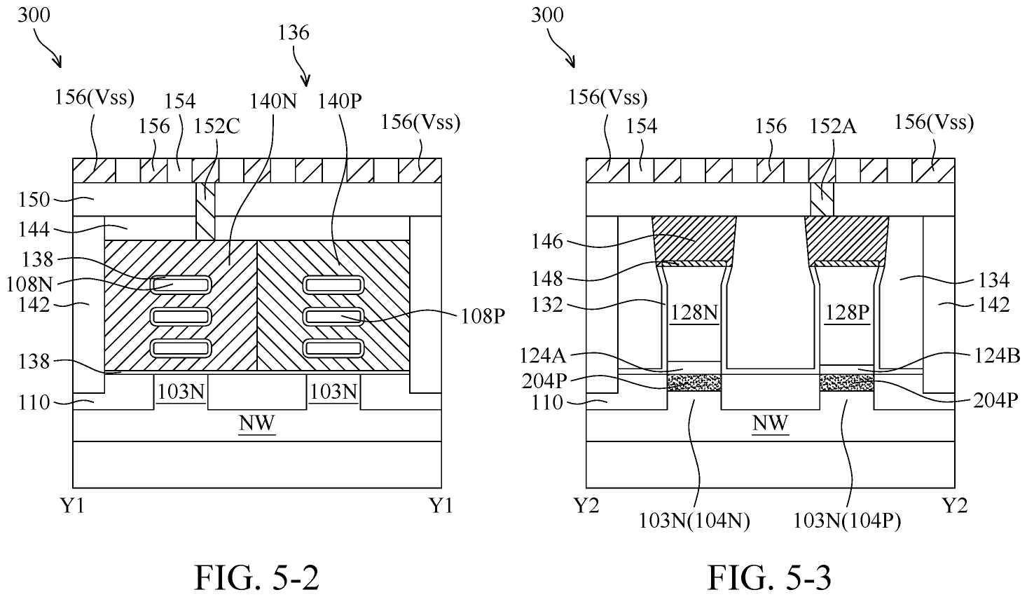

FIGS. 5-1, 5-2 and 5-3 illustrate a semiconductor structure 300 that is a modification of the semiconductor structure 200 of FIGS. 4B-1, 4B-2 and 4B-3, in accordance with some embodiments of the disclosure. In some embodiments, the doped regions 204P are also formed in the lower fin element 103N or the active region 104N under the dielectric isolation features 124A.

When the circuit of the cell region C1 operates at high voltage, a risk that the dielectric isolation features 124A/B are damaged and broken may increase. As a result, the isolation between the source/drain features 128N/P and lower fin element 103N may no longer be robust. In the embodiments of the present disclosure, the P-N junction formed between the p-type doped region 204P and the lower fin element 103N may prevent such a potential leakage path. The semiconductor device of the present disclosure with the leakage proof components (e.g., the dielectric isolation features 124A/B and the doped regions 204P) may allow for lower APT doses, or alternatively may allow for APT-free (skip) scheme. This may eliminate the effect of APT dose out-diffusion, thereby improving the threshold (Vt) mismatch issue of the resulting semiconductor device.

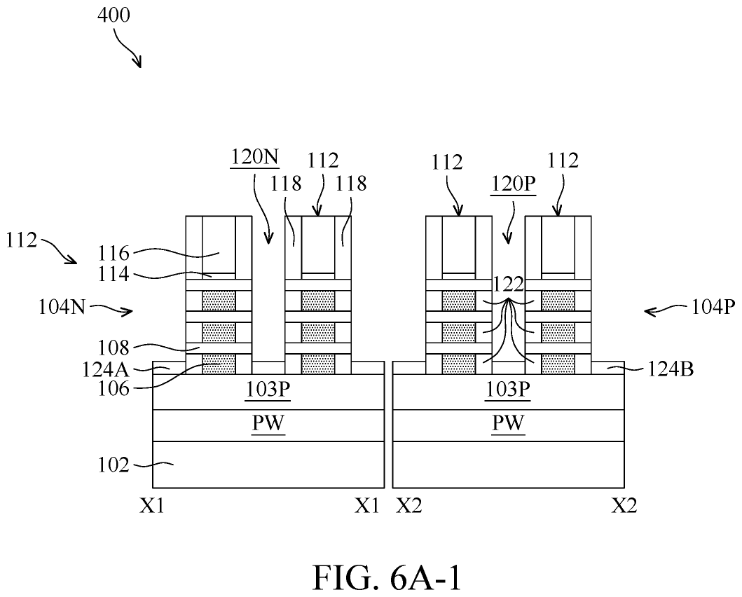

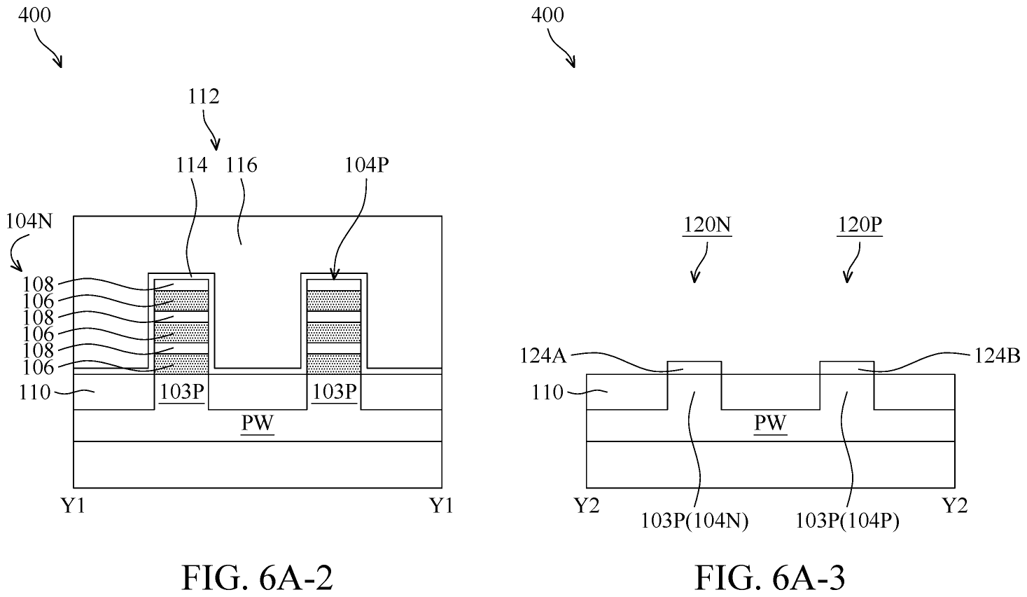

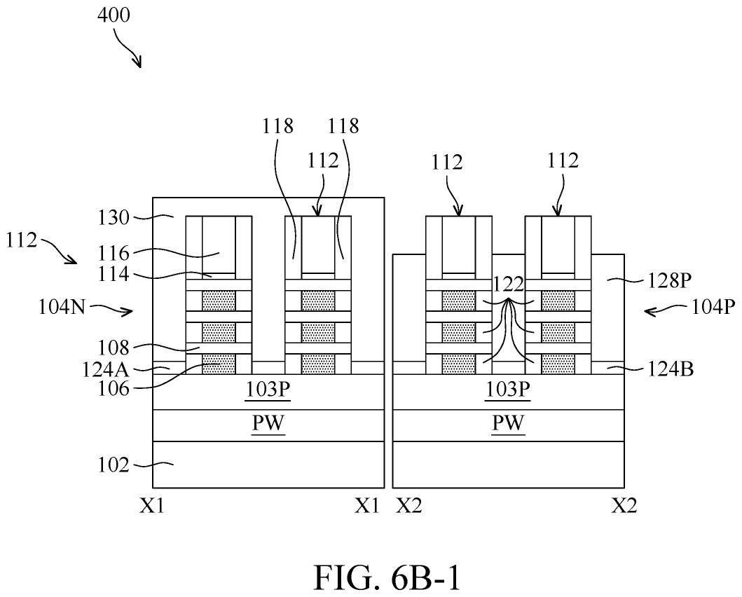

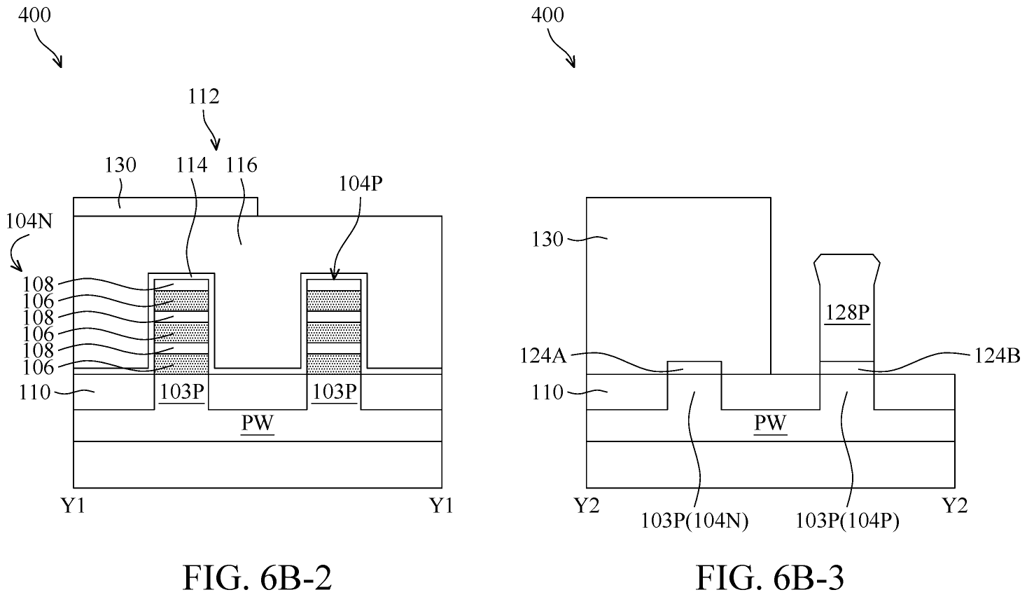

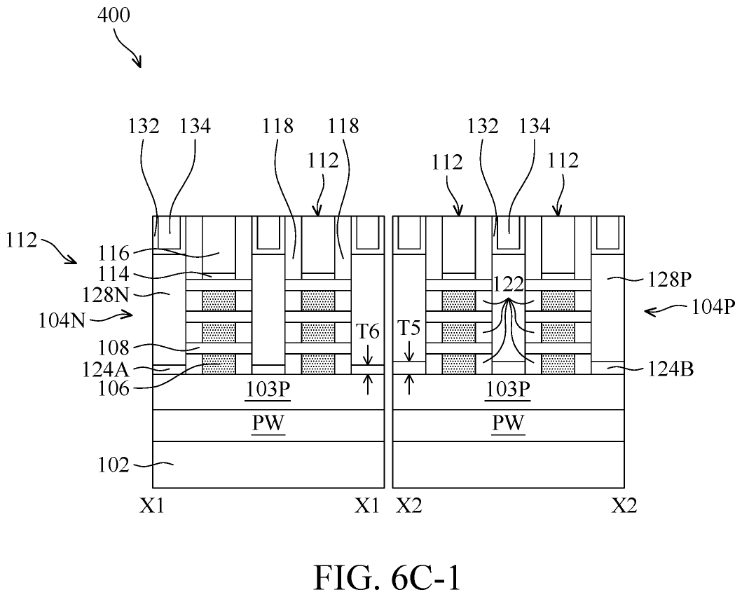

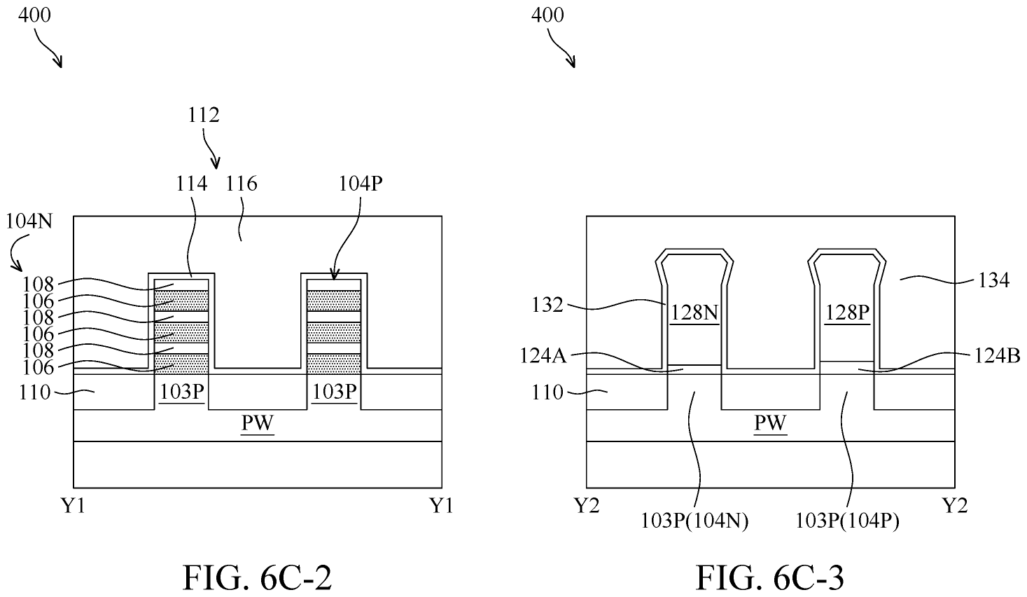

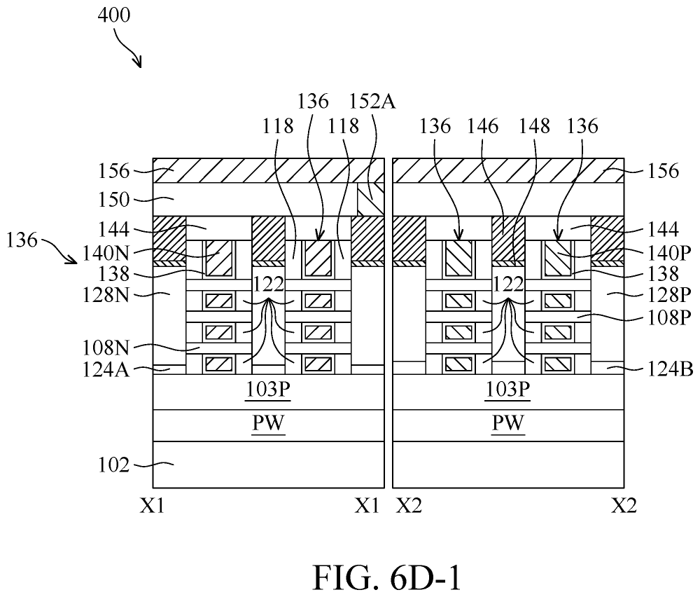

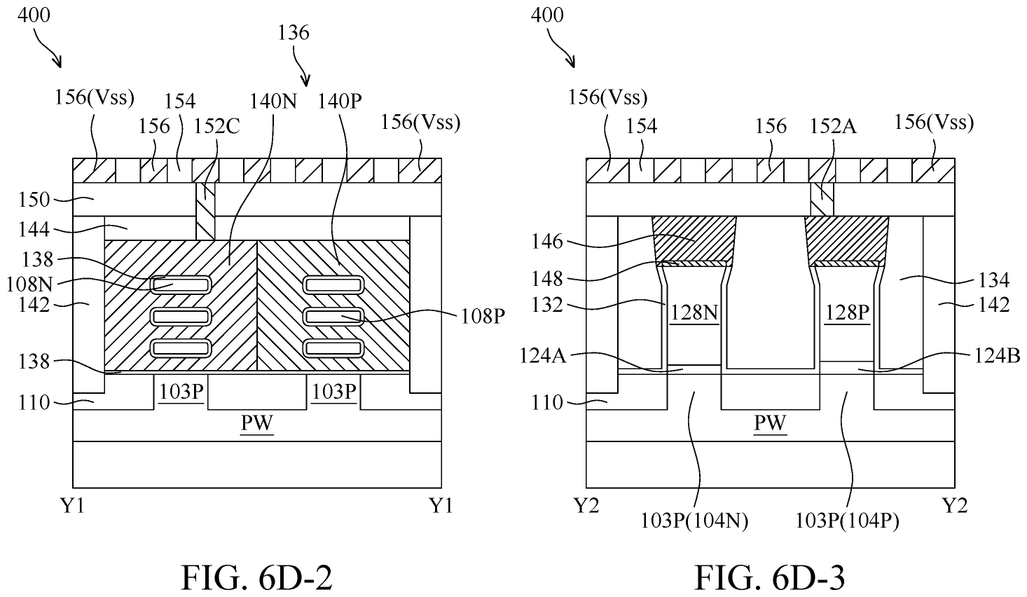

FIGS. 6A-1 through 6D-3 are cross-sectional views illustrating the formation of a semiconductor structure 400 at various intermediate stages, in accordance with some embodiments of the disclosure. The embodiments of FIGS. 6A-1 through 6D-3 are similar to the embodiments of FIGS. 3A through 3I-3 except both the active regions 104N and 104P are formed on a p-type well PW.

A p-type well PW is formed in the substrate 102 by one or more ion implantation processes, as shown in FIGS. 6A-1 to 6A-3, in accordance with some embodiments. In the ion implantation process, p-type dopants (such as boron (B) or BF₂) are implanted into the substrate 102 thereby forming the p-type well PW, in accordance with some embodiments. In some embodiments, the concentration of the dopants in the p-type well PW is in a range from about 10¹⁵/cm⁻³ to about 10¹⁸/cm⁻³.

An epitaxial stack including semiconductor layers 106 and 108 is formed over the p-type well PW, and then patterned into active regions 104N and 104P, as shown in FIGS. 6A-1 to 6A-3, in accordance with some embodiments. Both the active regions 104N and 104P are located on the p-type well PW, in accordance with some embodiments. The portion of the p-type well PW protruding from between the trenches serves as lower fin elements 103P of the active regions 104N and 104P, in accordance with some embodiments.

The steps described above in FIGS. 3A-1 to 3D-3 are performed, thereby forming an isolation structure 110, dummy gate structures 112, gate spacer layers 118, source/drain recesses 120N and 120P, dielectric isolation features 124A and 124B, as shown in FIGS. 6A-1 to 6A-3, in accordance with some embodiments.

A second source/drain mask 130 is formed to cover the active region 104N, and the active region 104P is exposed from the second source/drain mask 130, as shown in FIGS. 6B-1 to 6B-3, in accordance with some embodiments. Source/drain features 128P are formed on the second semiconductor layers 108 of the active region 104P, in accordance with some embodiments.

Afterward, the second source/drain mask 130 is removed using an etching process. A first source/drain mask 126 (not shown) is formed to cover the active region 104P and the source/drain features 128P, and the active region 104N is exposed from the first source/drain mask 126, in accordance with some embodiments. Source/drain features 128N are formed on the second semiconductor layers 108 of the active region 104N, as shown in FIGS. 6C-1 and 6C-3, in accordance with some embodiments.

In the etching process of removing the source/drain mask 130 and forming the first source/drain mask 126, the dielectric isolation features 124A are recessed and thus thinned down. As a result, the dielectric isolation features 124B are thicker than the dielectric isolation features 124A by 0.5 nm to about 5 nm. The thickness T5 of the dielectric isolation features 124B is in a range from about 1 nm to about 20 nm, e.g., about 1.5 nm to about 10 nm. The thickness T6 of the dielectric isolation features 124A is in a range from about 1 nm to about 20 nm, e.g., about 1.5 nm to about 10 nm.

Afterward, the first source/drain mask 126 is removed using an etching process. A contact etching stop layer 132 is formed to cover the source/drain features 128N and 128P, and a first interlayer dielectric layer 134 is formed over the contact etching stop layer 132, as shown in FIGS. 6C-1 to 6C-3, in accordance with some embodiments.

The steps described above in FIGS. 3H-1 to 3I-3 are performed, thereby forming the final gate stacks 136, the gat-cut structures 142, the dielectric cap layer 144, contact plugs 146, the second interlayer dielectric layer 150, the vias 152A, 152B and 152C, the first intermetal dielectric layer 154 and metal lines 156, as shown in FIGS. 6D-1, 6D-2 and 6D-3, in accordance with some embodiments.

In accordance with the embodiments of the present disclosure, the n-channel nanostructure transistors NMOSFET and the p-channel nanostructure transistors PMOSFET are formed in the same well (e.g., PW), and thus the leakage between neighboring wells with different conductivity types (e.g., n-type and p-type) may be prevented. Therefore, the performance of the resulting semiconductor device may be enhanced.

In addition, the formation of the dielectric isolation features 124A/B may block the leakage path of the bottom planar transistor. Furthermore, because the p-channel nanostructure transistors (PMOSFET) are formed in the p-type well PW instead of in the n-type well, the dielectric isolation features 124B with a greater thickness T5 is required to sufficiently isolate the source/drain feature 128P from the lower fin elements 103P. Therefore, the leakage issue of the body-to-gate interface region may be significantly reduced.

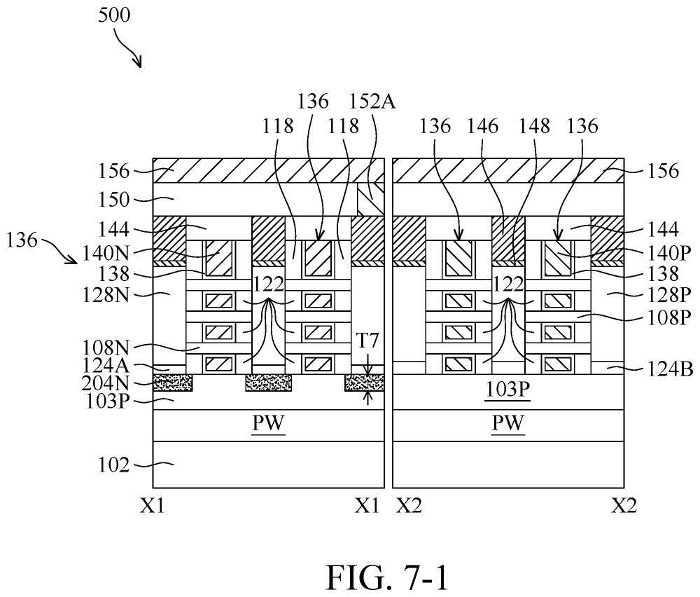

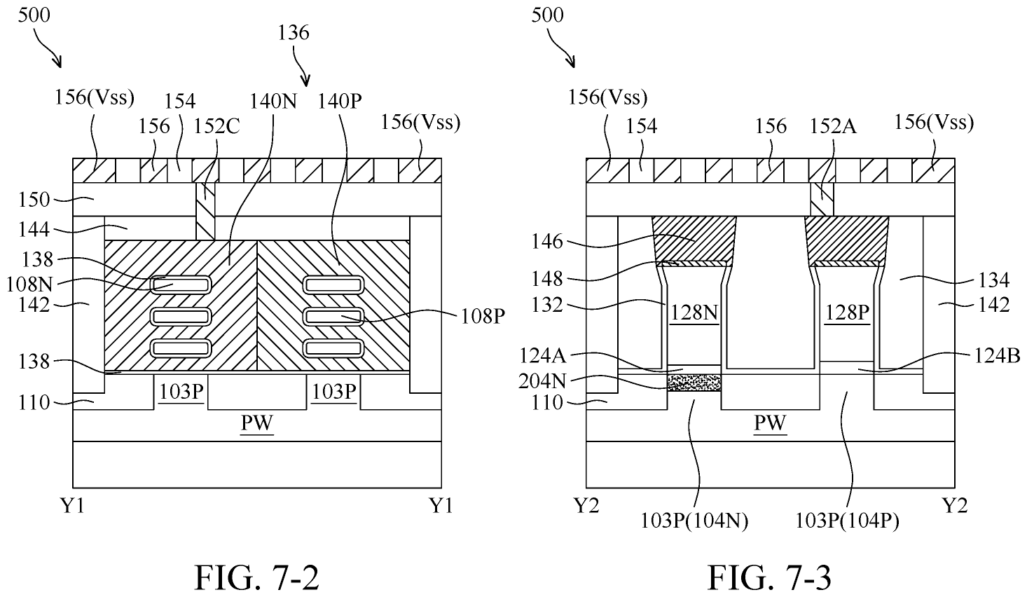

FIGS. 7-1, 7-2 and 7-3 are cross-sectional views of a semiconductor structure 500, in accordance with some embodiments of the disclosure. The embodiments of FIGS. 7-1 to 7-3 are similar to the embodiments of FIGS. 6A-1 through 6D-3 except doped regions 204N are formed under the dielectric isolation features 124A/B.

One the inner spacer layers 122 are formed, a patterned mask layer (not shown) is formed to cover the active regions 104P, and an implantation process is performed on the semiconductor structure 500 to form doped regions 204N in the lower fin element 103N of the active regions 104N, as shown in FIGS. 7-1 and 7-3, in accordance with some embodiments. In the implantation process, n-type dopants (e.g., phosphorus or arsenic) are introduced through the source/drain recess 120N and injected into the lower fin element 103P of the active regions 104N.

In some embodiments, the thickness T7 of the doped region 204N is in a range from about 3 nm to about 30 nm. In some embodiments, the concentration of the dopants in the doped region 204N is in a range from about 10¹⁷/cm⁻³ to about 10¹⁹/cm⁻³. In some embodiments, the concentration of doped region 204N is higher than the concentration of the lower fin element 103P (or the p-type well PW)

The doped region 204N extend directly under the inner spacer layers 122 (or the gate spacer layers 118), in accordance with some embodiment. In some embodiments, the dielectric isolation features 124A are formed on the doped regions 204N. In some embodiments, the doped regions 204N are wider than the dielectric isolation features 124A in the X direction. A P-N junction is formed between the n-type doped region 204N and the lower fin element 103P, in accordance with some embodiment. In the embodiments of the present disclosure, the P-N junction formed between the n-type doped region 204N and the lower fin element 103P may prevent a potential leakage path.

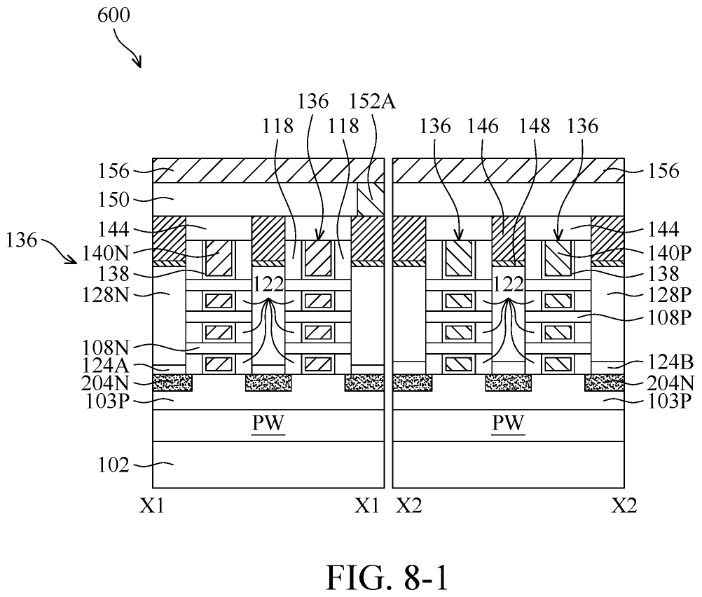

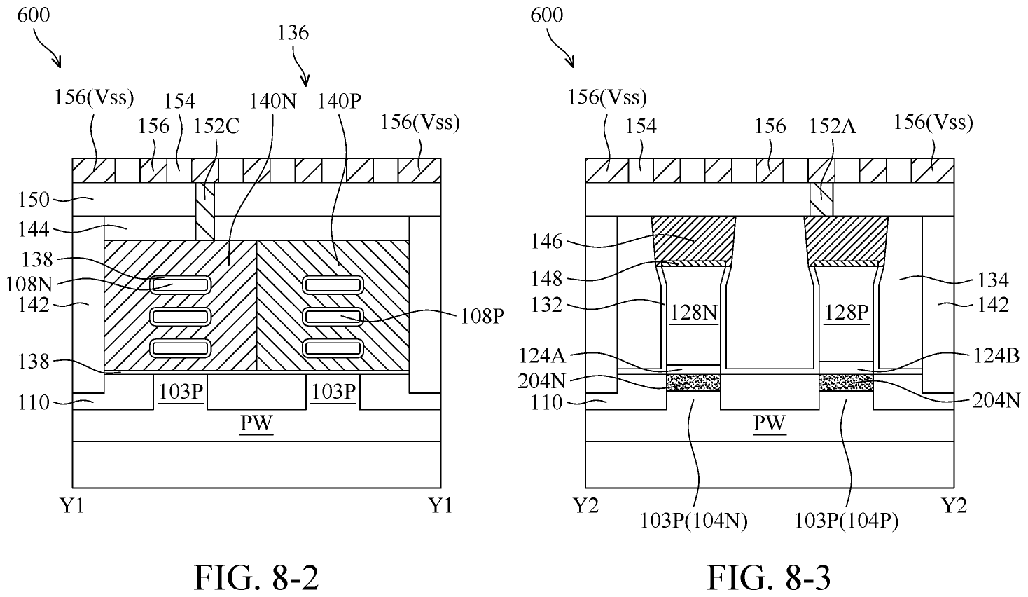

FIGS. 8-1, 8-2 and 8-3 illustrate a semiconductor structure 600 that is a modification of the semiconductor structure 500 of FIGS. 7-1, 7-2 and 7-3, in accordance with some embodiments of the disclosure. In some embodiments, the doped regions 204N are also formed in the lower fin element 103P or the active region 104P under the dielectric isolation features 124B.

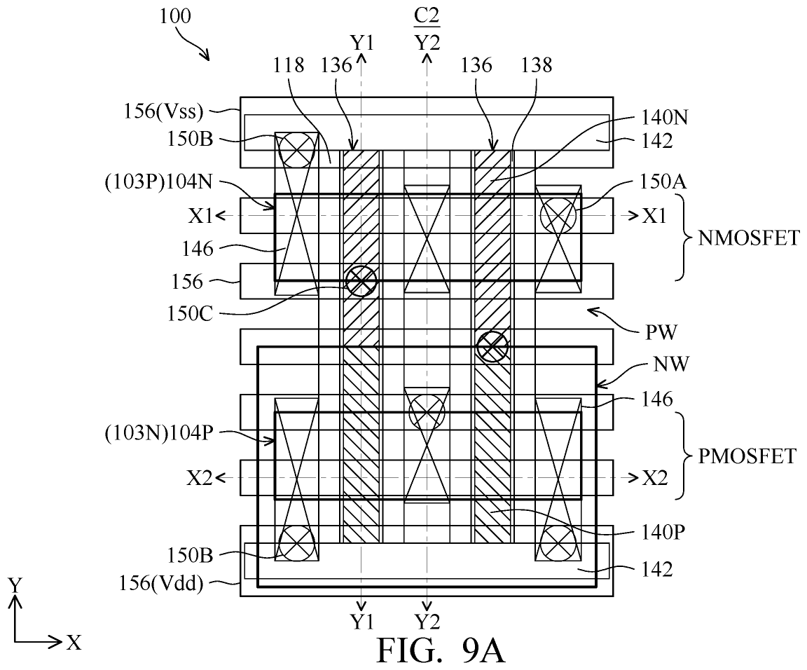

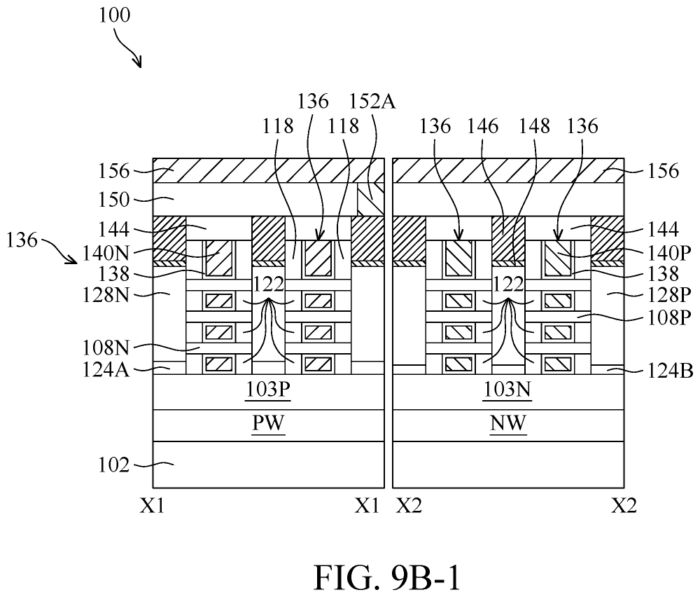

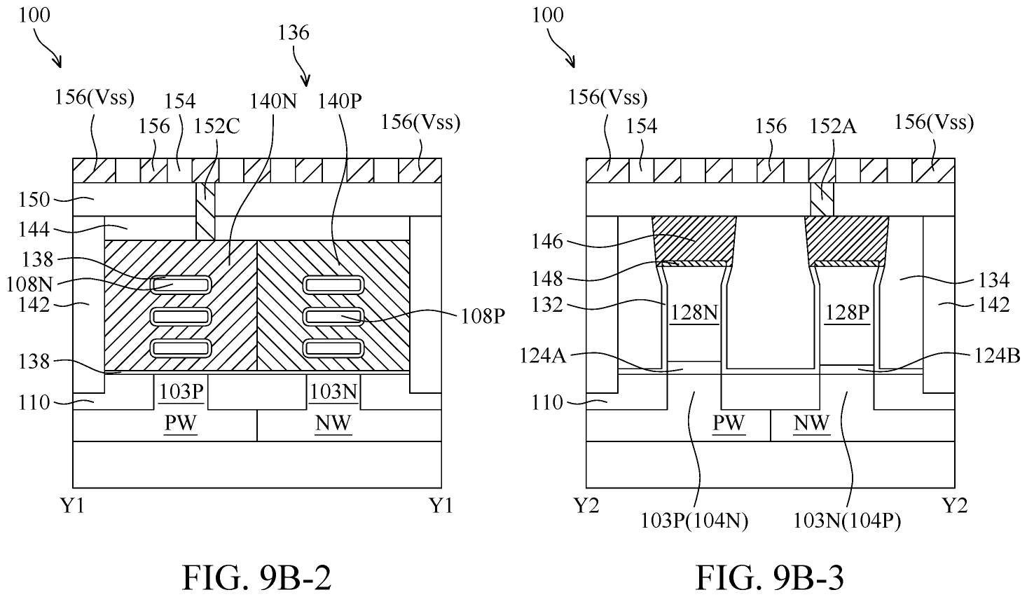

FIG. 9A is a layout of a cell region C2 of the semiconductor structure 100, in accordance with some embodiments. FIGS. 9B-1, 9B-2 and 9B-3 are cross-sectional views of the semiconductor structure 100 of FIG. 9A, in accordance with some embodiments of the disclosure.

Another region of the semiconductor structure 100 (or the substrate) is defined as a cell region C2, as shown in FIG. 9A, in accordance with some embodiments. The cell region C2 is similar to the cell region C1 of FIG. 2 except that the cell region C2 is located on both an n-type well NW and a p-type well PW. The cell region C2 may be separated from the cell region C1 by other cell regions. A functional circuit including four nanostructure transistors NMOSFET and PMOSFET is disposed in the cell region C2. The circuit in the cell region C2 may be coupled to the circuit in the cell region C1, in accordance with some embodiments.

In the cell region C2, an n-type well NW and a p-type well PW are formed in the substrate 102, and an active region 104N is formed over the p-type well PW and an active region 104P is formed over the n-type well NW, as shown FIGS. 9A to 9B-3, in accordance with some embodiments. In some embodiments, the metal gate electrode layer of the final gate stacks 136 includes an n-type work function metal material 140N over the p-type well PW and a p-type work function metal material 140P over the p-type well PW, as shown FIGS. 9A to 9B-3.

In the cell region C2, the n-channel nanostructure transistors NMOSFET are formed in the p-type well PW, and the p-channel nanostructure transistors PMOSFET. are formed in the n-type well NW, in accordance with some embodiments. The cell region C1 and cell region C2 may serve different applications (e.g., high-density applications, high-speed applications, memory device applications, etc.). Therefore, more design freedom of the resulting integrated circuits may be achieved.

FIGS. 10-1, 10-2 and 10-3 illustrate a semiconductor structure 700 that is a modification of the semiconductor structure 100 of FIGS. 3I-1, 3I-2 and 3I-3, in accordance with some embodiments of the disclosure. In some embodiments, the source/drain recesses 120N and 120P (not shown) are formed to extend a distance of about 5 nm to about 50 nm into the lower fin elements 103N and 103P. The dielectric isolation features 124A and 124B are partially embedded in the isolation structure 110, in accordance with some embodiments.

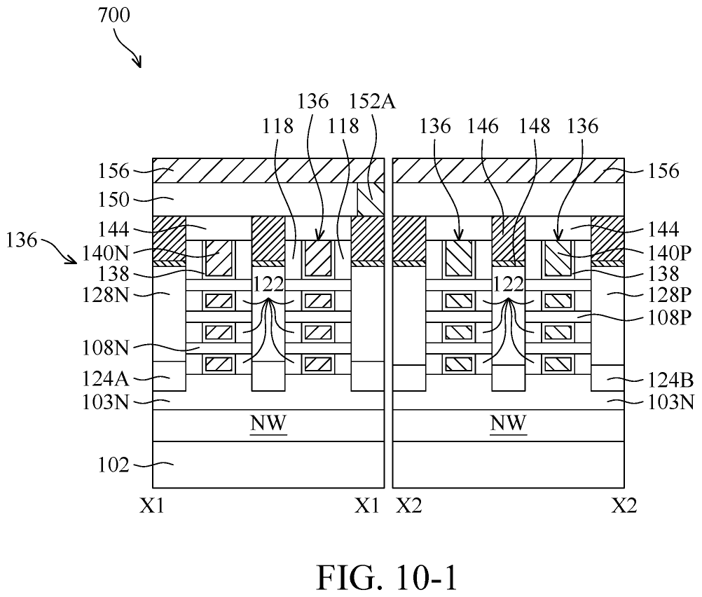

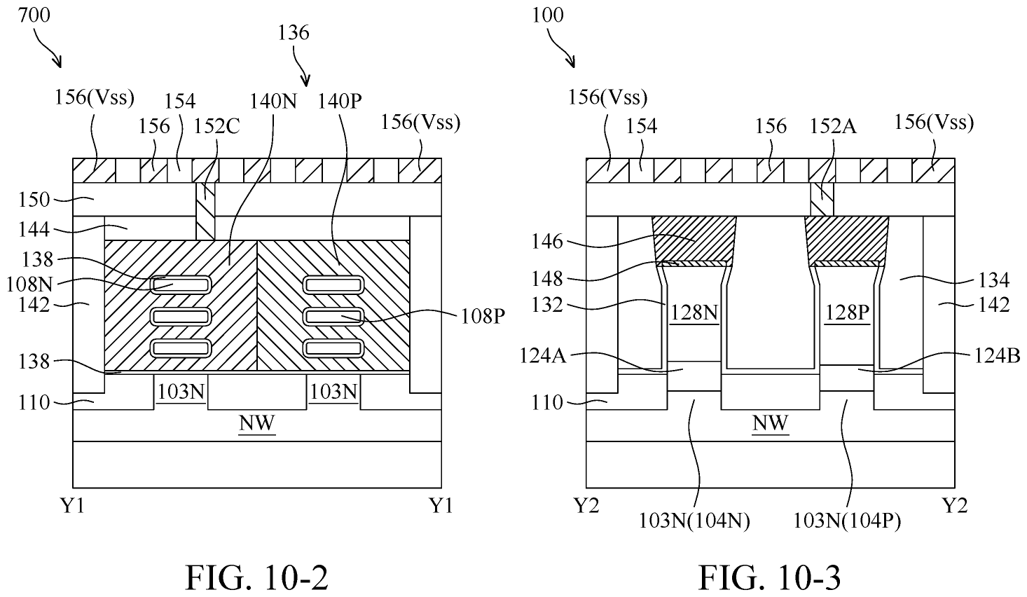

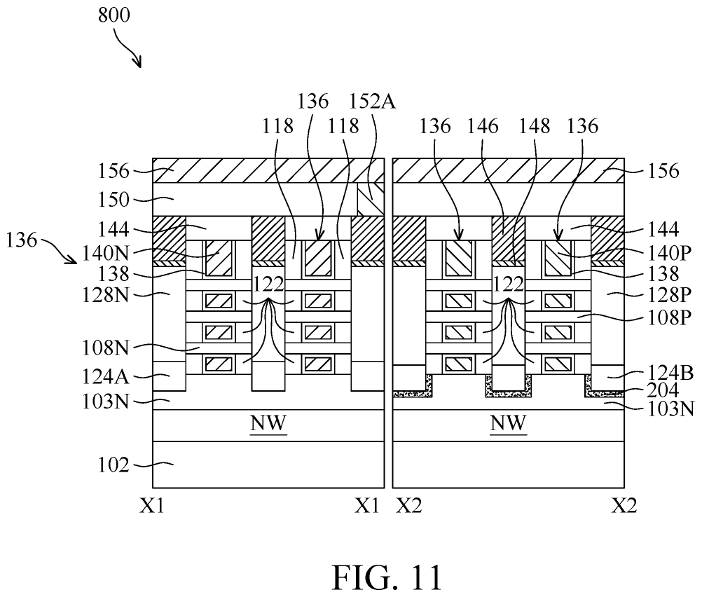

FIG. 11 illustrates a semiconductor structure 800 that is a modification of the semiconductor structure 700 of FIG. 10-2, in accordance with some embodiments of the disclosure. Doped regions 204 are formed in the lower fin element 103N of the active region 104P under the dielectric isolation features 124B, in accordance with some embodiments of the disclosure. The portion of the dielectric isolation features 124B embedded in the isolation structure 110 are surrounded by the doped regions 204, in accordance with some embodiments of the disclosure.

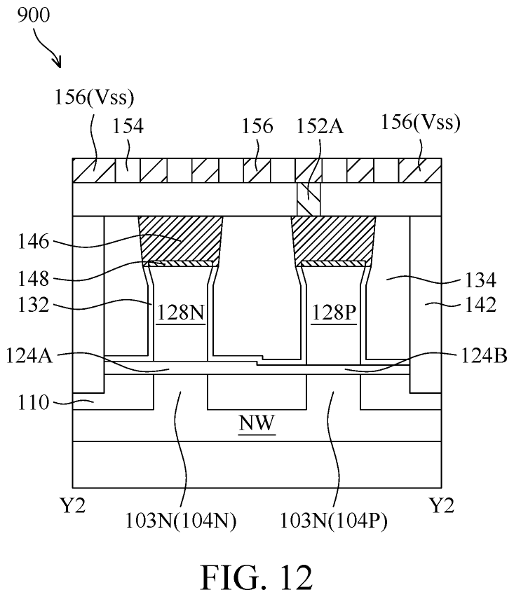

FIG. 12 illustrates a semiconductor structure 900 that is a modification of the semiconductor structure 100 of FIG. 3I-3, in accordance with some embodiments of the disclosure. The dielectric material of the dielectric isolation features 124A and 124B remain on the upper surface of the isolation structure 110, and continuously extends along the upper surface of the isolation structure 110 and the upper surfaces of the lower fin elements 103N, in accordance with some embodiments.

As described above, the aspect of the present disclosure is directed to a semiconductor structure including nanostructure transistors. The semiconductor structure includes the dielectric isolation features 124A/B between the source/drain features 128N/P and the lower fin element 103N/P, which may block the leakage path of the bottom planar transistor. Furthermore, the thicker dielectric isolation features 124A/B are formed over the well region with the same conductivity type as the conductivity type of nanostructure transistors formed thereon, whereas the thinner dielectric isolation features 124A/B are formed over the well region with the different conductivity type than the conductivity type of nanostructure transistors formed thereon. Therefore, the leakage issue of the body-to-gate interface region may be significantly reduced. In addition, the parasitic capacitance may be reduced (e.g., greater than 10% reduction), and thus the performance (e.g., speed) of the resulting semiconductor device may be enhanced.

Embodiments of a semiconductor structure and the method for forming the same may be provided. The semiconductor structure may include an n-channel nanostructure transistor and a p-channel nanostructure transistor on the same well, a first dielectric isolation feature under the first source/drain feature of the n-channel nanostructure transistor, and a second dielectric isolation feature under the second source/drain feature of the p-channel nanostructure transistor. In the embodiments where the well is an n-type well, the first dielectric isolation feature may be thicker than the second dielectric isolation feature. In the embodiments where the well is a p-type well, the second dielectric isolation feature may be thicker than the first dielectric isolation feature. Therefore, the leakage issue of the body-to-gate interface region may be significantly reduced.

In some embodiments, a method for forming a semiconductor structure is provided. The method includes forming a first first-type well in a substrate, forming a first active region and a second active region over the first-type well, etching the first active region and the second active region to form a first source/drain recess and a second source/drain recess, respectively, forming a first dielectric isolation feature and a second dielectric isolation feature in the first source/drain recess and the second source/drain recess, respectively, and forming a first n-type source/drain feature and a first p-type source/drain feature on the first dielectric isolation feature and the second dielectric isolation feature, respectively.

In some embodiments, a method for forming a semiconductor structure is provided. The method includes forming a first active region and a second active region over a substrate, forming a dummy gate structure across the first active region and the second active region, etching the first active region and a second active region to form a first recess and a second recess, forming a first dielectric isolation feature and a second dielectric isolation feature in the first recess and the second recess, respectively, forming a first source/drain mask to cover the second dielectric isolation feature, forming a first source/drain feature on the first dielectric isolation feature, removing the first source/drain mask, and forming a second source/drain mask to cover the first source/drain feature. After forming the second source/drain mask, the second dielectric isolation feature is thinner than the first dielectric layer. The method further includes forming a second source/drain feature on the second dielectric isolation feature.

In some embodiments, a semiconductor structure is provided. The semiconductor structure includes a first transistor and a second transistor in a first cell region. The first transistor includes a first plurality of nanostructures over a first lower fin element, and a first source/drain feature adjoining the first plurality of nanostructures. The second transistor includes a second plurality of nanostructures over a second lower fin element, and a second source/drain feature adjoining the second plurality of nanostructures. The semiconductor structure further includes a first dielectric isolation feature between the first source/drain feature and the first lower fin element, and a second dielectric isolation feature between the second source/drain feature and the second lower fin element. The first and second lower fin elements have a first conductivity type, the first source/drain feature has the first conductivity type, and the second source/drain feature has a second conductivity type. The second conductivity type is the opposite of the first conductivity type.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first first-type well in a substrate;
forming a first active region and a second active region over the first-type well;
etching the first active region and the second active region to form a first source/drain recess and a second source/drain recess, respectively;
forming a first dielectric isolation feature and a second dielectric isolation feature in the first source/drain recess and the second source/drain recess, respectively; and
forming a first n-type source/drain feature and a first p-type source/drain feature on the first dielectric isolation feature and the second dielectric isolation feature, respectively.

2. The method for forming the semiconductor structure as claimed in claim 1, wherein the first-type well is an n-type well, and the first dielectric isolation feature is thicker than the second dielectric isolation feature.

3. The method for forming the semiconductor structure as claimed in claim 1, wherein the first-type well is a p-type well, and the first dielectric isolation feature is thinner than the second dielectric isolation feature.

4. The method for forming the semiconductor structure as claimed in claim 1, further comprising:
forming a first mask layer covering the second dielectric isolation feature while exposing the first dielectric isolation feature, wherein the first n-type source/drain feature is formed after forming the first mask layer;
removing the first mask layer;
forming a second mask layer covering the first n-type source/drain feature, wherein the first p-type source/drain feature is formed after forming the second mask layer; and
removing the second mask layer.

5. The method for forming the semiconductor structure as claimed in claim 1, wherein each of the first active region and the second active region includes a lower fin element and first semiconductor layers and second semiconductor layers alternatingly stacked on the lower fin element.

6. The method for forming the semiconductor structure as claimed in claim 5, wherein the first dielectric isolation feature is formed over the lower fin element of the first active region, and the second dielectric isolation feature is formed over the lower fin element of the second active region.

7. The method for forming the semiconductor structure as claimed in claim 5, further comprising:
implanting a dopant through a second source/drain recess into the lower fin element of the second active region to form a doped region, wherein the second dielectric isolation feature is formed on the doped region.

8. The method for forming the semiconductor structure as claimed in claim 7, wherein the doped region is wider than the second dielectric isolation feature.

9. A method for forming a semiconductor structure, comprising:
forming a first active region and a second active region over a substrate;
forming a dummy gate structure across the first active region and the second active region;
etching the first active region and the second active region to form a first recess and a second recess;
forming a first dielectric isolation feature and a second dielectric isolation feature in the first recess and the second recess, respectively;
forming a first source/drain mask to cover the second dielectric isolation feature;
forming a first source/drain feature on the first dielectric isolation feature;
removing the first source/drain mask;
forming a second source/drain mask to cover the first source/drain feature, wherein after forming the second source/drain mask, the second dielectric isolation feature is thinner than the first dielectric layer; and
forming a second source/drain feature on the second dielectric isolation feature.

10. The method for forming the semiconductor structure as claimed in claim 9, further comprising:
implanting a first-type dopant into the substrate to form a first well;
alternatingly stacking first semiconductor layers and second semiconductor layers; and
etching the first semiconductor layers and the second semiconductor layers and the first well to form trenches, wherein a first portion of the first well protruding from the trenches forms a first lower fin element of the first active region, and a second portion of the first well protruding from the trenches forms a second lower fin element of the second active region.

11. The method for forming the semiconductor structure as claimed in claim 10, further comprising:
implanting a second-type dopant into the second lower fin element to form a doped region, the first-type dopant and the second-type dopant have different conductivity types.

12. The method for forming the semiconductor structure as claimed in claim 11, further comprising:
forming a gate space layer on a sidewall of the dummy gate structure, wherein the gate spacer layer overlaps a P-N junction formed between the doped region and the lower fin element.

13. The method for forming the semiconductor structure as claimed in claim 12, wherein a portion of the second dielectric isolation feature is embedded in the doped region.

14. The method for forming the semiconductor structure as claimed in claim 10, further comprising:
removing the dummy gate structure;
removing the first semiconductor layers of each of the first active region and the second active region, wherein the second semiconductor layers of the first active region form a first plurality of nanostructures, and the second semiconductor structures of the second active region form a second plurality of nanostructures;
forming a first work function layer to surround the first plurality of nanostructures; and
forming a second work function layer to surround the second plurality of nanostructures.

15. A semiconductor structure, comprising:
a first transistor and a second transistor in a first cell region, wherein the first transistor includes a first plurality of nanostructures over a first lower fin element, and a first source/drain feature adjoining the first plurality of nanostructures, and the second transistor includes a second plurality of nanostructures over a second lower fin element, and a second source/drain feature adjoining the second plurality of nanostructures;
a first dielectric isolation feature between the first source/drain feature and the first lower fin element; and
a second dielectric isolation feature between the second source/drain feature and the second lower fin element,
wherein the first and second lower fin elements have a first conductivity type, the first source/drain feature has the first conductivity type, and the second source/drain feature has a second conductivity type opposite to the first conductivity type.

16. The semiconductor structure as claimed in claim 15, further comprising:
a gate stack wrapping around the first plurality of nanostructures; and
a plurality of inner spacer layers between the gate stack and the first source/drain feature, wherein in a plan view, a sidewall of the dielectric isolation feature is substantially aligned with a sidewall of one of the inner spacer layers.

17. The semiconductor structure as claimed in claim 15, further comprising:
a first doped region in the second lower fin element and having the second conductivity type.

18. The semiconductor structure as claimed in claim 17, wherein the first doped region is in contact with the second dielectric isolation structure.

19. The semiconductor structure as claimed in claim 15, wherein the first dielectric isolation feature is thicker than the second dielectric isolation feature.

20. The semiconductor structure as claimed in claim 15, further comprising:
a third transistor and a fourth transistor in a second cell region, wherein the third transistor includes a third plurality of nanostructures over a third lower fin element, and a third source/drain feature adjoining the third plurality of nanostructures, and the fourth transistor includes a fourth plurality of nanostructures over a fourth lower fin element, and a fourth source/drain feature adjoining the fourth plurality of nanostructures,
wherein the third lower fin element has the second conductivity type, the fourth lower fin element has the first conductivity type, the third source/drain feature has the first conductivity type, and the fourth source/drain feature has the second conductivity type.
